(19) United States
(12) Patent Application Publication
(10) Pub. No.: US 2024/0365543 A1
(43) Pub. Date: Oct. 31, 2024

(54) SEMICONDUCTOR DEVICE AND DATA STORAGE SYSTEM INCLUDING SEMICONDUCTOR DEVICE

(71) Applicant: Samsung Electronics Co., Ltd., Suwon-si (KR)

(72) Inventors: Taegon LEE, Suwon-si (KR); Minkyu KANG, Suwon-si (KR); Sungjun KIM, Suwon-si (KR); Woongseop LEE, Suwon-si (KR); Eunsuk CHO, Suwon-si (KR); Jongyoon CHOI, Suwon-si (KR); Hyungyu HWANG, Suwon-si (KR)

(73) Assignee: Samsung Electronics Co., Ltd., Suwon-si (KR)

(21) Appl. No.: 18/435,328

(22) Filed: Feb. 7, 2024

(30) Foreign Application Priority Data
Apr. 27, 2023 (KR) 10-2023-0055380

(51) Int. Cl. H10B 43/27; H10B 41/10; H10B 41/27; H10B 43/10; H01L 23/00; H01L 25/065; H10B 80/00

(52) U.S. Cl. CPC H10B 43/27; H10B 41/10; H10B 41/27; H10B 43/10; H01L 24/32; H01L 24/33; H01L 24/48; H01L 24/73; H01L 25/0657; H01L 2224/32145; H01L 2224/32225; H01L 2224/33181; H01L 2224/48091; H01L 2224/48145; H01L 2224/48227; H01L 2224/73215; H01L 2224/73265; H01L 2225/06506; H01L 2225/0651; H01L 2225/06562; H10B 80/00

(57) ABSTRACT

A semiconductor device comprising; a first semiconductor structure including a substrate, circuit elements on the substrate, and circuit interconnection lines on the circuit elements; and a second semiconductor structure on the first semiconductor structure. The second semiconductor structure includes, a plate layer, a plurality of gate electrodes spaced apart from each other and stacked on the plate layer in a first direction, perpendicular to an upper surface of the plate layer, the gate electrodes including a lower select gate electrode, memory gate electrodes, and an upper select gate electrode sequentially stacked, channel structures passing through the lower select gate electrode and the memory gate electrodes and extending in the first direction, stud structures passing through the upper select gate electrode and respectively connected to the channel structures.

### CROSS-REFERENCE TO RELATED APPLICATION(S)

This application claims benefit of priority to Korean Patent Application No. 10-2023-0055380 filed on Apr. 27, 2023 in the Korean Intellectual Property Office, the disclosure of which is incorporated herein by reference in its entirety.

### BACKGROUND

Inventive concepts relate, in general, to a semiconductor device and/or a data storage system including the same.

In an electronic system requiring data storage, a semiconductor device capable of storing high-capacity data is in demand. Accordingly, a method of increasing a data storage capacity of a semiconductor device has been researched. For example, as a method of increasing data storage capacity of a semiconductor device, a semiconductor device including memory cells arranged three-dimensionally, instead of memory cells arranged two-dimensionally, has been proposed.

### SUMMARY

Various example embodiments may provide a semiconductor device having an improved degree of integration.

Alternatively or additionally, various example embodiments may provide a data storage system including a semiconductor device having an improved degree of integration.

According to some example embodiments, there is provided a semiconductor device comprising; a first semiconductor structure including a substrate, circuit elements on the substrate, and circuit interconnection lines on the circuit elements; and a second semiconductor structure on the first semiconductor structure. The second semiconductor structure includes, a plate layer, a plurality of gate electrodes spaced apart from each other and stacked on the plate layer in a first direction, perpendicular to an upper surface of the plate layer, the gate electrodes including a lower select gate electrode, memory gate electrodes, and an upper select gate electrode sequentially stacked, channel structures passing through the lower select gate electrode and the memory gate electrodes and extending in the first direction, stud structures passing through the upper select gate electrode and respectively connected to the channel structures, an upper gate dielectric layer surrounding the stud structures and recessed into the upper select gate electrode in a horizontal direction parallel to the upper surface of the plate layer, the upper gate dielectric layer on an outside of each of the stud structures, and upper isolation regions between the stud structures, passing through the upper select gate electrode and extending in a second direction, perpendicular to the first direction. Each of the stud structures includes an upper channel layer covering an internal sidewall and a bottom surface of a stud hole passing through the upper select gate electrode, an upper filling insulating layer at least partially filling the stud hole on the upper channel layer.

Alternatively or additionally, according to some example embodiments there is provided a semiconductor device comprising; a plate layer, a plurality of gate electrodes spaced apart from each other and stacked on the plate layer in a first direction, perpendicular to an upper surface of the plate layer, the gate electrodes including first gate electrodes in a lower portion thereof and at least one second gate electrode on the first gate electrodes, channel structures passing through the first gate electrodes and extending in the first direction, stud structures passing through the second gate electrode and respectively connected to the channel structures, an upper gate dielectric layer on a side surface of each of the stud structures, the upper gate dielectric layer in contact with the second gate electrode, and upper isolation regions between the stud structures, passing through the second gate electrode and extending in a second direction, perpendicular to the first direction.

Alternatively or additionally, according to some example embodiments there is provided a data storage system comprising; a semiconductor storage device including a first semiconductor structure including circuit elements, a second semiconductor structure on a surface of the first semiconductor structure, and input/output pads electrically connected to the circuit elements, and a controller electrically connected to the semiconductor storage device through the input/output pad, the controller configured to control the semiconductor storage device. The second semiconductor structure includes, a plate layer, a plurality of gate electrodes spaced apart from each other and stacked on the plate layer in a first direction, perpendicular to an upper surface of the plate layer, the gate electrodes including first gate electrodes in a lower portion thereof and at least one second gate electrode on the first gate electrodes, channel structures passing through the first gate electrodes and extending in the first direction, stud structures passing through the second gate electrode and respectively connected to the channel structures, an upper gate dielectric layer protruding toward the second gate electrode on a side surface of each of the stud structures, and upper isolation regions passing between the stud structures, through the second gate electrode and extending in a second direction, perpendicular to the first direction.

### BRIEF DESCRIPTION OF DRAWINGS

The above and other aspects, features, and advantages of various example embodiments may be more clearly understood from the following detailed description, taken in conjunction with the accompanying drawings, in which:

FIG. 1 is a schematic plan view of a semiconductor device according to some example embodiments;

FIG. 2 is a schematic cross-sectional view of a semiconductor device according to some example embodiments;

FIGS. 3A and 3B are schematic partially enlarged views of portions of a semiconductor device according to some example embodiments;

FIGS. 4A to 4C are schematic partially enlarged views of a semiconductor device according to some example embodiments;

FIGS. 5 to 7 is a schematic cross-sectional view of a semiconductor device according to some example embodiments;

FIG. 8 is a schematic plan view of a semiconductor device according to some example embodiments;

FIG. 9 is a schematic cross-sectional view of a semiconductor device according to some example embodiments;

FIGS. 10A to 10O are schematic cross-sectional views illustrating a method of manufacturing a semiconductor device according to some example embodiments;

FIGS. 11A to 11K are schematic cross-sectional views illustrating a method of manufacturing a semiconductor device according to some example embodiments;

FIG. 12 is a schematic diagram illustrating a data storage system including a semiconductor device according to some example embodiments;

FIG. 13 is a schematic perspective view of a data storage system including a semiconductor device according to some example embodiments; and

FIG. 14 is a schematic cross-sectional view of a semiconductor package according to some example embodiments.

### DETAILED DESCRIPTION

Reference will now be made in detail to embodiments, examples of which are illustrated in the accompanying drawings, wherein like reference numerals refer to like elements throughout. In this regard, some example embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

It will be understood that when an element such as a layer, film, region, or substrate is referred to as being “on” another element, it may be directly on the other element or intervening elements may also be present. In contrast, when an element is referred to as being “directly on” another element, there are no intervening elements present. It will further be understood that when an element is referred to as being “on” another element, it may be above or beneath or adjacent (e.g., horizontally adjacent) to the other element.

It will be understood that elements and/or properties thereof (e.g., structures, surfaces, directions, or the like), which may be referred to as being “perpendicular,” “parallel,” “coplanar,” or the like with regard to other elements and/or properties thereof (e.g., structures, surfaces, directions, or the like) may be “perpendicular,” “parallel,” “coplanar,” or the like or may be “substantially perpendicular,” “substantially parallel,” “substantially coplanar,” respectively, with regard to the other elements and/or properties thereof.

It will be understood that elements and/or properties thereof may be recited herein as being “the same” or “equal” as other elements, and it will be further understood that elements and/or properties thereof recited herein as being “identical” to, “the same” as, or “equal” to other elements may be “identical” to, “the same” as, or “equal” to or “substantially identical” to, “substantially the same” as or “substantially equal” to the other elements and/or properties thereof. Elements and/or properties thereof that are “substantially identical” to, “substantially the same” as or “substantially equal” to other elements and/or properties thereof will be understood to include elements and/or properties thereof that are identical to, the same as, or equal to the other elements and/or properties thereof within manufacturing tolerances and/or material tolerances. Elements and/or properties thereof that are identical or substantially identical to and/or the same or substantially the same as other elements and/or properties thereof may be structurally the same or substantially the same, functionally the same or substantially the same, and/or compositionally the same or substantially the same.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

Hereinafter, example embodiments of the inventive concepts will be described below with reference to the accompanying drawings.

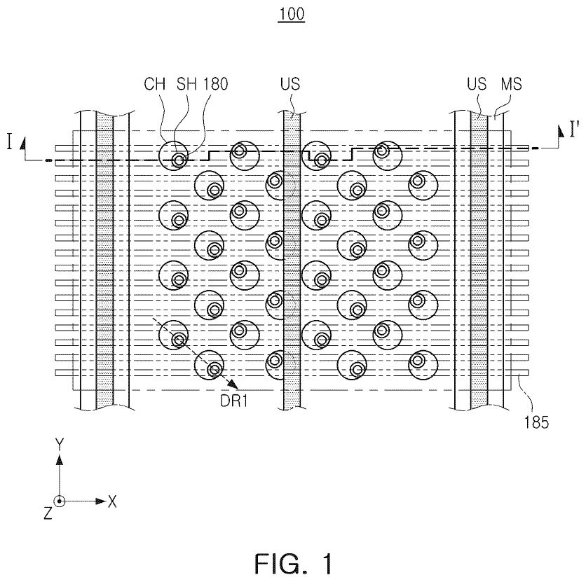

FIG. 1 is a schematic plan view of a semiconductor device according to some example embodiments.

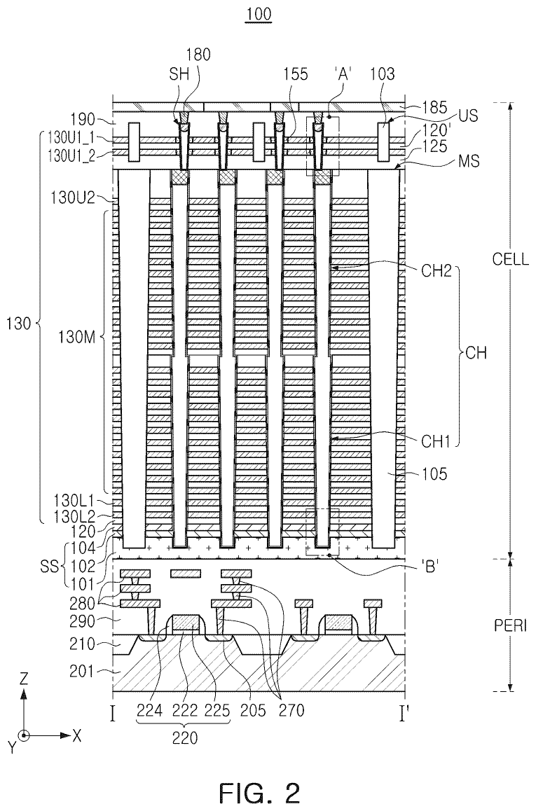

FIG. 2 is a schematic cross-sectional view of a semiconductor device according to some example embodiments. FIG. 2 illustrates a cross-section taken along line I-I′ of FIG. 1.

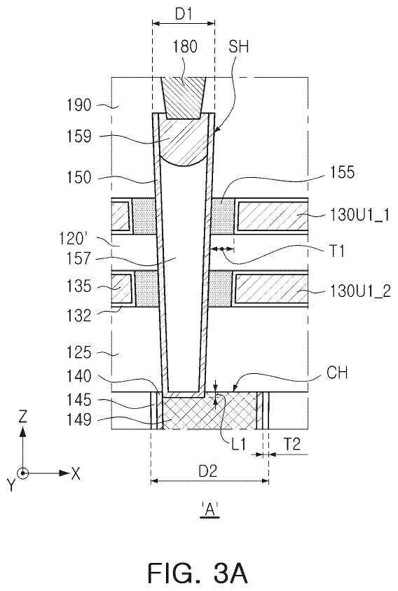

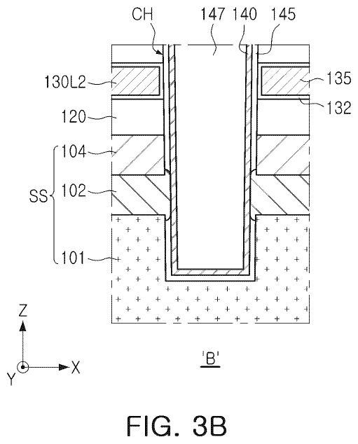

FIGS. 3A and 3B are schematic partially enlarged views illustrating an enlarged portion of a semiconductor device according to some example embodiments. FIG. 3A is an enlarged view of region “A” of FIG. 2, and FIG. 3B is an enlarged view of region “B” of FIG. 2.

Referring to FIGS. 1 to 3B, a semiconductor device 100 may include a peripheral circuit region PERI, a first semiconductor structure including a substrate 201, and a memory cell region CELL, a second semiconductor structure including a plate layer 101. The memory cell region CELL may be disposed on the peripheral circuit region PERI. Conversely, in further example embodiments, the memory cell region CELL may be disposed below the peripheral circuit region PERI.

The peripheral circuit region PERI may include a substrate 201, impurity regions 205 and element isolation layers 210 in the substrate 201, circuit elements 220 disposed on the substrate 201, a peripheral region insulating layer 290, circuit contact plugs 270, and circuit interconnection lines 280.

The substrate 201 may have an upper surface extending in an X-direction and a Y-direction. In the substrate 201, an active region may be defined as the region between the element isolation layers 210. The impurity regions 205 including impurities may be disposed in a portion of the active region. The substrate 201 may include a semiconductor material, such as one or more of a group IV semiconductor, a group III-V compound semiconductor, or a group II-VI compound semiconductor. The substrate 201 may be provided as a bulk wafer and/or an epitaxial layer.

The circuit elements 220 may include a planar transistor. Each of the circuit elements 220 may include a circuit gate dielectric layer 222, a spacer layer 224, and a circuit gate electrode 225. On first and second sides of the circuit gate electrode 225, the impurity regions 205 may be disposed as source/drain regions within the substrate 201. The impurity regions may include dopants such as, but not limited to, one or more of boron (B), phosphorus (P), arsenic (As), carbon (C), etc.

On the substrate 201, the peripheral region insulating layer 290 may be disposed on the circuit element 220. The peripheral region insulating layer 290 may include a plurality of insulating layers formed in different process operations. The peripheral region insulating layer 290 may be formed or include an insulating material.

The circuit contact plugs 270 and the circuit interconnection lines 280 may form a circuit interconnection structure electrically connected to the circuit elements 220 and the impurity regions 205. The circuit contact plugs 270 may have a cylindrical shape, and the circuit interconnection lines 280 may have a linear shape. An electrical signal may be applied to the circuit element 220 by the circuit contact plugs 270 and the circuit interconnection lines 280. In a region not illustrated, the circuit contact plugs 270 may also be connected to the circuit gate electrode 225. The circuit interconnection lines 280 may be connected to the circuit contact plugs 270, have a linear shape, and may be disposed in a plurality of layers. The circuit contact plugs 270 and the circuit interconnection lines 280 may include a conductive material, for example, tungsten (W), copper (Cu), aluminum (Al), and the like, and respective components may further include a diffusion barrier. In some example embodiments, the number of layers of the circuit contact plugs 270 and the circuit interconnection lines 280 may be changed in various manners.

The memory cell region CELL may include a source structure SS, gate electrodes 130 stacked on the source structure SS, interlayer insulating layers 120 and 120′ stacked alternately with the gate electrodes 130, channel structures CH and stud structures SH disposed to pass through a stack structure of the gate electrodes 130, upper gate dielectric layers 155 on outsides of the stud structures SH, lower isolation regions MS passing through a portion of the gate electrodes 130 disposed on a lower portion thereof, upper isolation regions US passing through a portion of the gate electrodes 130 disposed on an upper portion thereof, cell contact plugs 180 on the stud structures SH, and bit lines 185 on the cell contact plugs 180. The memory cell region CELL may further include an intermediate insulating layer 125 covering the lower isolation regions MS and the channel structures CH, and a cell region insulating layer 190 covering the gate electrodes 130.

The source structure SS may include a plate layer 101, a first horizontal conductive layer 102, and a second horizontal conductive layer 104 sequentially stacked. However, in some example embodiments, the number of conductive layers forming the source structure SS may be changed in various manners.

The plate layer 101 may be in the form of a plate, and may function as at least a portion of a common source line of the semiconductor device 100. The plate layer 101 may have an upper surface extending in the X-direction and the Y-direction. The plate layer 101 may include a conductive material. For example, the plate layer 101 may include a semiconductor material, such as a group IV semiconductor, a group III-V compound semiconductor, or a group II-VI compound semiconductor. For example, the group IV semiconductor may include silicon, germanium, or silicon-germanium. The plate layer 101 may further include impurities. The plate layer 101 may be provided as a polycrystalline semiconductor layer such as a polycrystalline silicon layer or an epitaxial layer.

The first and second horizontal conductive layers 102 and 104 may be sequentially stacked on an upper surface of the plate layer 101. The first horizontal conductive layer 102 may function as a portion of a common source line of the semiconductor device 100, and may function as a common source line, together with the plate layer 101, for example. As illustrated in FIG. 3B, the first horizontal conductive layer 102 may be directly connected to a lower channel layer 140 on a circumference of the lower channel layer 140.

The first and second horizontal conductive layers 102 and 104 may include a semiconductor material, for example, polycrystalline silicon. In this case, at least the first horizontal conductive layer 102 may be a layer doped with conductivity-type impurities the same as that of the plate layer 101, and the second horizontal conductive layer 104 may be a doped layer or may be a layer including impurities diffused from the first horizontal conductive layer 102. However, the material of the second horizontal conductive layer 104 is not limited to a semiconductor material, and may be replaced with an insulating layer.

The gate electrodes 130 may be vertically spaced apart and stacked on the plate layer 101 to form a stack structure together with the interlayer insulating layers 120 and 120′. The stack structure may include vertically stacked lower and upper stack structures. However, in some example embodiments, the stack structure may be formed of a single stack structure.

The gate electrodes 130 may include first upper gate electrodes 130U1_1 and 130U1_2 forming string select transistors, a second upper gate electrode 130U2 forming an erase transistor, memory gate electrodes 130M forming a plurality of memory cells, a first lower gate electrode 130L1 forming the erase transistor, and a second lower gate electrode 130L2 forming a ground select transistor. The second upper gate electrode 130U2 may be referred to as the erase gate electrode, or in some example embodiments the lower gate electrodes 130L1 and/or 130L2 could be referred to as the erase gate electrode. The number of memory gate electrodes 130M, forming memory cells, may be determined depending on the capacity of the semiconductor device 100. In the various example embodiments, the first upper gate electrodes 130U1_1 and 130U1_2 may include two gate electrodes. However, in some example embodiments, each of the first upper gate electrodes 130U1_1 and 130U1_2, the second upper gate electrode 130U2, the first lower gate electrode 130L1, and the second lower gate electrode 130L2 may be one to four or more.

The first upper gate electrodes 130U1_1 and 130U1_2 and the second lower gate electrode 130L2 may also be referred to as an upper select gate electrode and a lower select gate electrode, respectively. In addition, the second lower gate electrode 130L2, the first lower gate electrode 130L1, the memory gate electrodes 130M, and the second upper gate electrode 130U2 sequentially disposed from below may be referred to as first gate electrodes, and the first upper gate electrodes 130U1_1 and 130U1_2 may be referred to as second gate electrodes. A thickness of each of the first upper gate electrodes 130U1_1 and 130U1_2, that is, a thickness of the second gate electrode, may be equal to or less than a thickness of each of the first gate electrodes. This may be because, unlike the memory gate electrodes 130M, the first upper gate electrodes 130U1_1 and 130U1_2 forming a transistor with the stud structures SH, and thus are not restricted by memory cell characteristics.

In some example embodiments, positions of the first upper gate electrodes 130U1_1 and 130U1_2 and the second upper gate electrode 130U2 may be exchanged with each other, or positions of the first lower gate electrode 130L1 and the second lower gate electrode 130L2 may be exchanged with each other. In some example embodiments, the second upper gate electrode 130U2 and/or the first lower gate electrode 130L1 may be omitted. In some example embodiments, a portion of the memory gate electrodes 130M may be a dummy gate electrode.

All of the gate electrodes 130 may include the same material. For example, the memory gate electrodes 130M and the first upper gate electrodes 130U1_1 and 130U1_2 may have the same internal structure and may include the same material. Each of the gate electrodes 130 may include a gate barrier layer 132 and a gate conductive layer 135, as illustrated in FIGS. 3A and 3B. The gate barrier layer 132 may surround an upper surface, a lower surface, and side surfaces of the gate conductive layer 135. The gate barrier layer 132 may include tungsten nitride (WN), tantalum nitride (TaN), titanium nitride (TiN), or combinations thereof. The gate conductive layer 135 may include a metal material, such as tungsten (W). In some example embodiments, the gate conductive layer 135 may include polycrystalline silicon or a metal silicide material. However, example embodiments are not limited thereto.

The interlayer insulating layers 120 and 120′ and the intermediate insulating layer 125 may be disposed between the gate electrodes 130. The interlayer insulating layers 120 and 120′ may include lower interlayer insulating layers 120 in contact with the channel structures CH and upper interlayer insulating layers 120′ in contact with the stud structures SH. In the same manner as the gate electrodes 130, the interlayer insulating layers 120 and 120′ may also be disposed to be spaced apart from each other in a direction, perpendicular to the upper surface of the plate layer 101. Portions of the interlayer insulating layers 120 and 120′ may have different thicknesses. For example, the interlayer insulating layer 120 disposed to be adjacent to a region in which the first channel structure CH1 and the second channel structure CH2 are connected and the interlayer insulating layer 120 on the second upper gate electrode 130U2 may have a relatively large thickness. The intermediate insulating layer 125 may be disposed between the lower isolation regions MS and the second upper gate electrode 130U2. The interlayer insulating layers 120 and the intermediate insulating layer 125 may include an insulating material such as silicon oxide, silicon nitride, silicon oxynitride, and the like, however example embodiments are not limited thereto.

The channel structures CH may extend in a Z-direction through the gate electrodes 130 except for the first upper gate electrodes 130U1_1 and 130U1_2, and may be connected to the plate layer 101. The channel structures CH may form one memory cell string together with the stud structures SH, and may be spaced apart from each other while forming rows and columns on the plate layer 101. As illustrated in FIG. 1, in an X-Y plane, the channel structures CH may be disposed to form a lattice pattern or to have a zigzag shape in one direction. In some example embodiments, with respect to the channel structures CH, eight channel structures CH may be disposed to have a zigzag shape in the X-direction between lower isolation regions MS adjacent to each other, and may be repeatedly disposed to have the above-described shape. The channel structures CH may have a columnar shape and have inclined side surfaces becoming narrower as a distance to the plate layer 101 decreases.

The channel structures CH may include vertically stacked first and second channel structures CH1 and CH2. The channel structures CH may have a form in which the first channel structures CH1 and the second channel structures CH2 are connected to each other, and may have a bent portion due to a difference in width in a connection region. However, in some example embodiments, the number of channel structures stacked in the Z-direction may be changed in various manners.

As illustrated in FIG. 3B, each of the channel structures CH may include a lower channel layer 140, a lower gate dielectric layer 145, a lower filling insulating layer 147, and a lower pad 149 disposed in a channel hole. The lower channel layer 140 may be formed to have an annular shape surrounding the lower filling insulating layer 147 therein. However, in some example embodiments, the lower channel layer 140 may have a columnar shape such as a cylindrical shape or a prismatic shape, without the lower filling insulating layer 147. The lower channel layer 140 may be connected to the first horizontal conductive layer 102 thereunder. The lower channel layer 140 may include a semiconductor material such as polycrystalline silicon or single-crystalline silicon, however example embodiments are not limited thereto.

The lower gate dielectric layer 145 may be disposed between the gate electrodes 130 and the lower channel layer 140. Although not specifically illustrated, the lower gate dielectric layer 145 may include a tunneling layer, a charge storage layer, and a blocking layer sequentially stacked from the lower channel layer 140. The tunneling layer may tunnel charges into the charge storage layer, and may include, for example, silicon oxide (SiO₂), silicon nitride (Si₃N₄), silicon oxynitride (SiON), or combinations thereof, however example embodiments are not limited thereto. The charge storage layer may be a charge trapping layer or a floating gate conductive layer. The blocking layer may include silicon oxide (SiO₂), silicon nitride (Si₃N₄), silicon oxynitride (SiON), a high-K dielectric material, or combinations thereof, however example embodiments are not limited thereto. In some example embodiments, at least a portion of the lower gate dielectric layer 145 may extend in a horizontal direction along the gate electrodes 130.

The lower pad 149 may be disposed only on an upper end of the upper second channel structure CH2. The lower pad 149 may include, for example, doped polycrystalline silicon, epitaxial silicon, or the like, but is not limited thereto.

The lower channel layer 140, the lower gate dielectric layer 145, and the lower filling insulating layer 147 may be connected to each other between the first channel structure CH1 and the second channel structure CH2. The interlayer insulating layer 120, surrounding an upper end of the first channel structure CH1, may have a relatively large thickness. However, in some example embodiments, a thickness of each of the interlayer insulating layers 120 may be changed in various manners.

The stud structures SH may be disposed on the channel structures CH, respectively. The stud structures SH may extend in the Z-direction through the first upper gate electrodes 130U1_1 and 130U1_2, and may be connected to the channel structures CH, respectively. The stud structures SH may form a string select transistor together with, for example, the first upper gate electrodes 130U1_1 and 130U1_2 and the upper gate dielectric layers 155. As illustrated in FIG. 1, the stud structures SH may be disposed to be shifted from the channel structures CH in a first horizontal direction DR1. The first horizontal direction DR1 may be a diagonal direction along the arrangement of the channel structures CH, and may be a direction inclined with respect to the X-direction and the Y-direction.

As illustrated in FIG. 3A, the stud structure SH may be disposed to partially recess an upper end of the channel structure CH. In some example embodiments, a recess depth L1 may be changed in various manners. A diameter D1 of the stud structure SH may be less than a diameter D2 of the channel structure CH. The diameters D1 and D2 may refer to a diameter of an upper end or an average diameter.

Each of the stud structures SH may include an upper channel layer 150, an upper filling insulating layer 157, and an upper pad 159 disposed in the stud hole. The upper channel layer 150 may be disposed to have a substantially uniform thickness to cover an internal sidewall and a bottom surface of the stud hole. The upper channel layer 150 may be directly connected to the lower pad 149 of the channel structure CH, and may be further connected to the lower channel layer 140. The upper filling insulating layer 157 may be disposed to fill the stud hole on an inside of the upper channel layer 150. The upper pad 159 may be connected to the upper channel layer 150, and may be disposed to partially recess the upper filling insulating layer 157 and fill an upper end of the stud hole.

The description of materials of the upper channel layer 150, the upper filling insulating layer 157, and the upper pad 159 may be applied to the lower channel layer 140, the lower filling insulating layer 147, and the lower pad 149 described above in the same manner.

The upper gate dielectric layers 155 may be disposed on side surfaces of the stud structures SH on outsides of the stud structures SH, that is, on an external side surface of the upper channel layer 150. The upper gate dielectric layers 155 may be in contact with the upper channel layer 150, and may be disposed to outwardly recess the first upper gate electrodes 130U1_1 and 130U1_2 in a horizontal direction. The upper gate dielectric layers 155 may be disposed on the external side surface of the upper channel layer 150 to protrude toward the first upper gate electrodes 130U1_1 and 130U1_2, and may be in contact with the upper gate electrodes 130U1_1 and 130U1_2. The upper gate dielectric layers 155 may be disposed on levels substantially the same as those of the first upper gate electrodes 130U1_1 and 130U1_2. The upper gate dielectric layers 155 may entirely surround side surfaces of the stud structure SH on the levels. The upper gate dielectric layers 155 may be surrounded by first upper gate electrodes 130U1_1 and 130U1_2, respectively, and may be spaced apart from each other in the Z-direction.

A first thickness T1 of the upper gate dielectric layer 155 on the external side surface of the upper channel layer 150 may be equal to or greater than a second thickness T2 of the lower gate dielectric layer 145 of the channel structure CH, but the various example embodiments are not limited thereto. The first thickness T1 may be in a range of about 20% or more of the diameter D1 of the stud structure SH, for example, in a range of about 20% to about 100%. The first thickness T1 may be selected within the above-described range in consideration of operating conditions of string select transistors, a thickness of each of the first upper gate electrodes 130U1_1 and 130U1_2, a level of process difficulty, or the like. In some example embodiments, the first thickness T1 may be, for example, about 20% to about 40% of the diameter D1 of the stud structure SH. In some example embodiments, the first thickness T1 may be greater than a half of the diameter D1 of the stud structure SH. The upper gate dielectric layer 155 may not be disposed in the stud hole in which the stud structure SH is disposed, but may be disposed on an outside of the stud structure SH, thereby reducing (and/or minimizing) a limitation in thickness, as described above. In comparative example, when an upper gate dielectric layer is disposed in the stud hole, a portion of the upper gate dielectric layer may need to be removed from a bottom surface of the stud hole in order to electrically connect the upper channel layer 150 to the channel structure CH. Considering such a process, in comparative example, it may be difficult to form a thickness of the upper gate dielectric layer greater than the half of the diameter D1 of the stud structure SH, and it may be substantially difficult to form the thickness of the upper gate dielectric layer greater than about 30% of the diameter D1. However, in some example embodiments, the first thickness T1 may be increased regardless of the diameter D1 of the stud structure SH.

The upper gate dielectric layer 155 may include, for example, silicon oxide (SiO₂), silicon nitride (Si₃N₄), silicon oxynitride (SiON), a high-K dielectric material, or combinations thereof, however example embodiments are not limited thereto. The material of the upper gate dielectric layer 155 may be the same as or different from that of the lower gate dielectric layer 145. The upper gate dielectric layer 155 may be disposed as a single layer or a plurality of layers. In some example embodiments, when the upper gate dielectric layer 155 includes a first dielectric layer and a second dielectric layer, the first dielectric layer may be disposed to cover an upper surface and a lower surface of the second dielectric layer, and an external side surface of the second dielectric layer facing the gate electrode 130, for example.

The lower isolation regions MS may pass through a portion of the gate electrodes 130 and extend in the Y-direction. As illustrated in FIG. 1, the lower isolation regions MS may be disposed to be parallel to each other. The lower isolation regions MS may pass through the gate electrodes 130 except for the first upper gate electrodes 130U1_1 and 130U1_2 on the plate layer 101 and further pass through the first and second horizontal conductive layers 102 and 104 thereunder to be connected to the plate layer 101.

A gate isolation insulating layer 105 may be disposed in each of the lower isolation regions MS. The gate isolation insulating layer 105 may have a shape having a width decreasing toward the plate layer 101 due to a high aspect ratio thereof. The gate isolation insulating layer 105 may include an insulating material, for example, silicon oxide, silicon nitride, or silicon oxynitride, or the like, however example embodiments are not limited thereto.

As illustrated in FIG. 1, the upper isolation regions US may be disposed on the lower isolation regions MS and further disposed between the lower isolation regions MS adjacent to each other. The upper isolation regions US may extend in the Y-direction. The upper isolation regions US may pass through the first upper gate electrodes 130U1_1 and 130U1_2 disposed on an uppermost portion of the gate electrodes 130. As illustrated in FIG. 2, the upper isolation regions US may divide the first upper gate electrodes 130U1_1 and 130U1_2 in the X-direction. A portion of the upper isolation regions US may overlap the lower isolation regions MS in the Z-direction. In the X-direction, a width of each of the upper isolation regions US may be less than a width of each of the lower isolation regions MS. In some example embodiments, the upper isolation regions US may be disposed on the channel structures CH, such that an area of the memory cell region CELL may be reduced (and/or minimized), as compared to a case in which the upper isolation regions US are disposed on a level the same as that of a portion of the channel structures CH.

Each of the upper isolation regions US may include an upper isolation insulating layer 103. The upper isolation insulating layer 103 may include an insulating material, for example, silicon oxide, silicon nitride, or silicon oxynitride, however example embodiments are not limited thereto.

The cell contact plugs 180 and the bit lines 185 may form a cell interconnection structure electrically connected to memory cells in the memory cell region CELL. The cell contact plugs 180 may be connected to the stud structures SH, and may be electrically connected to the channel structures CH and the stud structures SH. The cell contact plugs 180 may be disposed to partially recess upper portions of the stud structures SH, but example embodiments are not limited thereto. The cell contact plugs 180 may electrically connect the channel structures CH and the stud structures SH to the upper bit lines 185.

In various example embodiments, the cell contact plugs 180 may be aligned such that central axes thereof correspond to each other on the stud structures SH. In detail, vertical central axes of the cell contact plugs 180 may substantially correspond to vertical central axes of the stud structures SH. As illustrated in FIG. 1, centers of the cell contact plugs 180 and the stud structures SH may correspond to each other on a plan view.

The bit lines 185 may be disposed to extend in the X-direction. As illustrated in FIG. 1, the bit lines 185 may be electrically connected to a single stud structure SH through a cell contact plug 180 between upper isolation regions US adjacent to each other. The cell contact plugs 180 may include metal, for example, tungsten (W), copper (Cu), aluminum (Al), or the like, however example embodiments are not limited thereto.

The cell region insulating layer 190 may be disposed to cover a stack structure of the gate electrodes 130, the stud structure SH, and the like. The cell region insulating layer 190 may be formed of an insulating material or may be formed of a plurality of insulating layers.

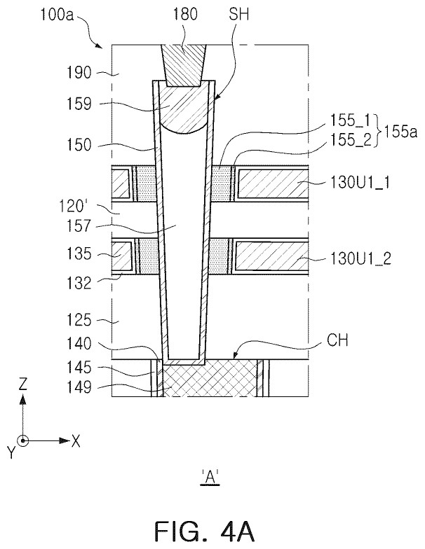

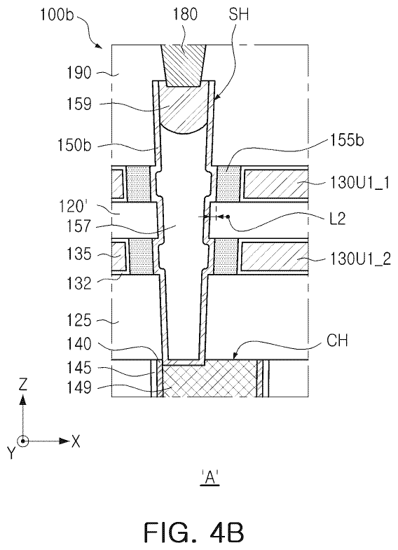

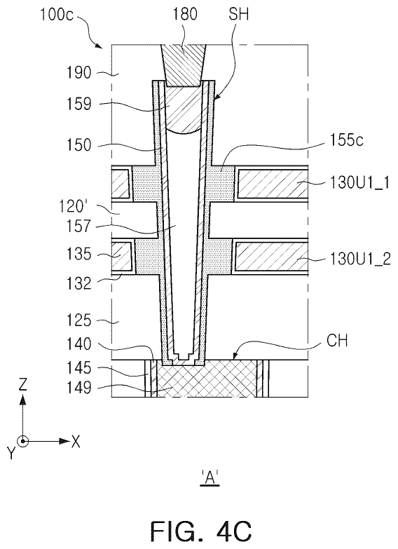

FIGS. 4A to 4C are schematic partially enlarged views of a semiconductor device according to some example embodiments. FIGS. 4A to 4C each illustrate a region corresponding to that of FIG. 3A.

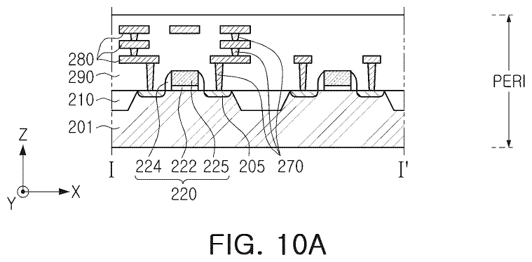

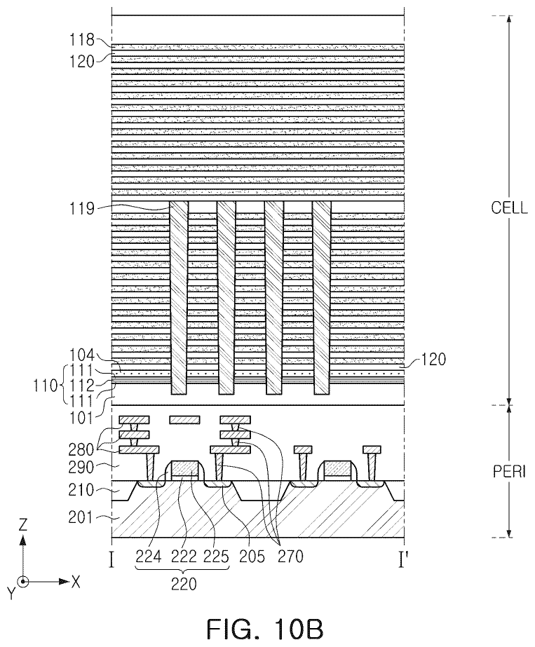

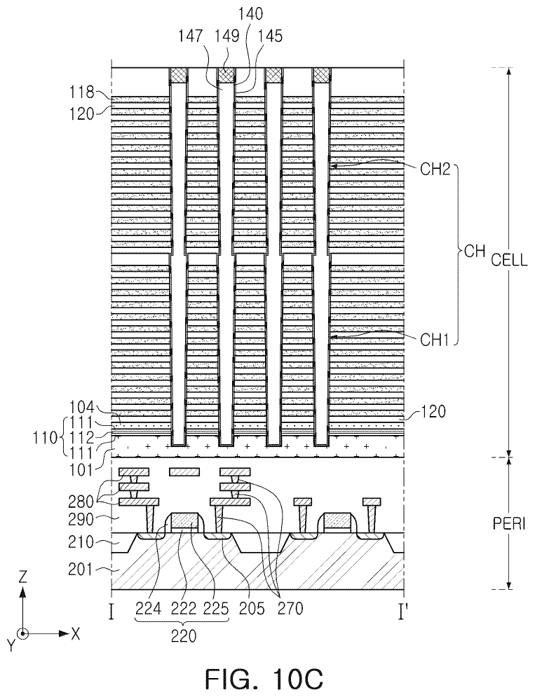

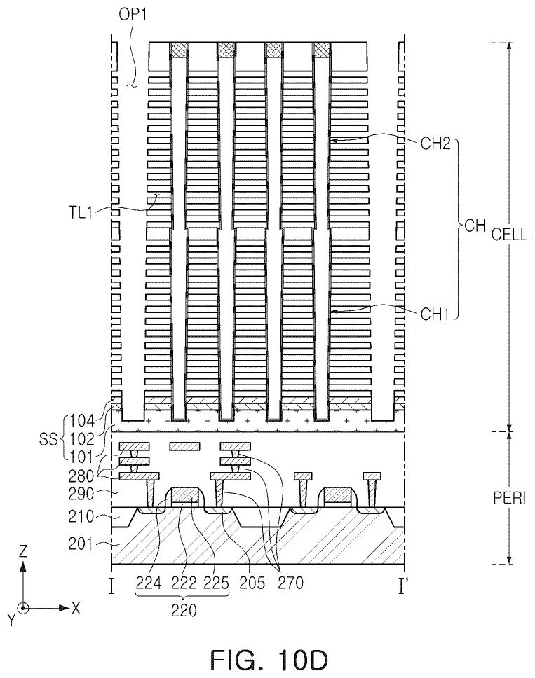

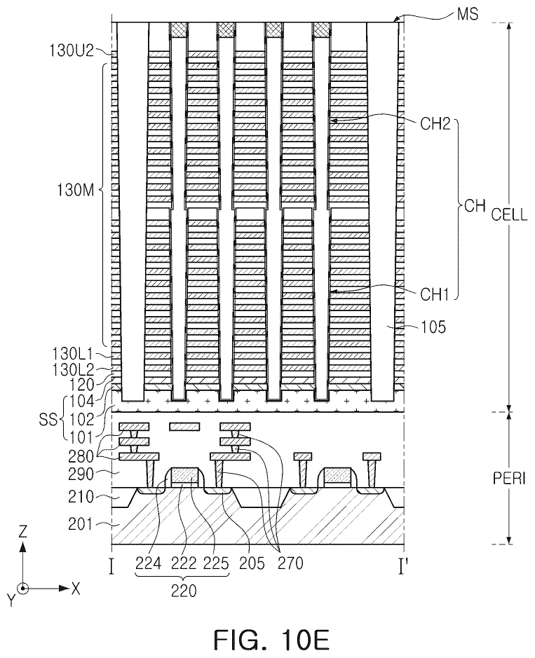

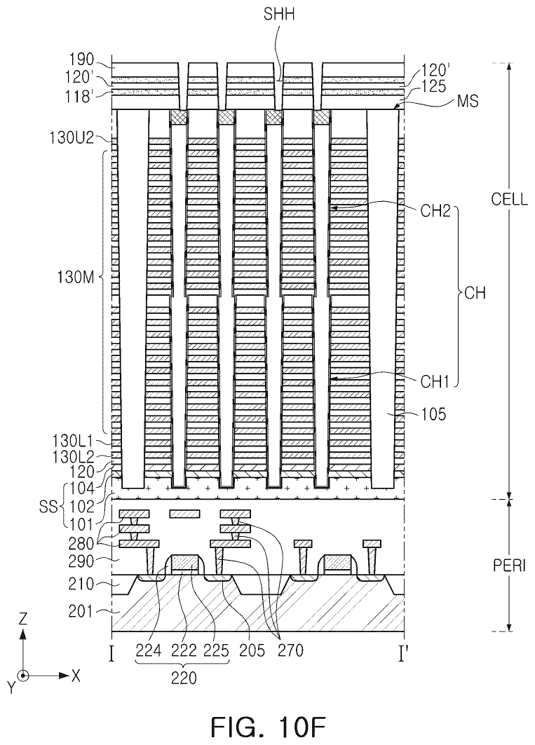

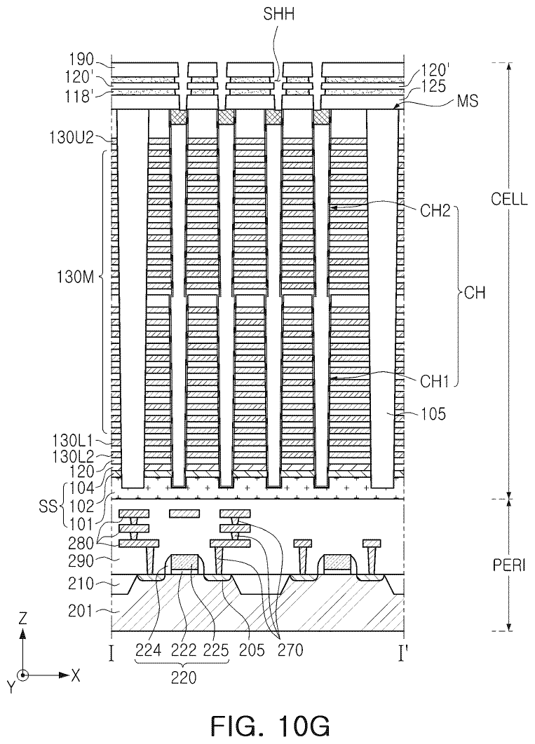

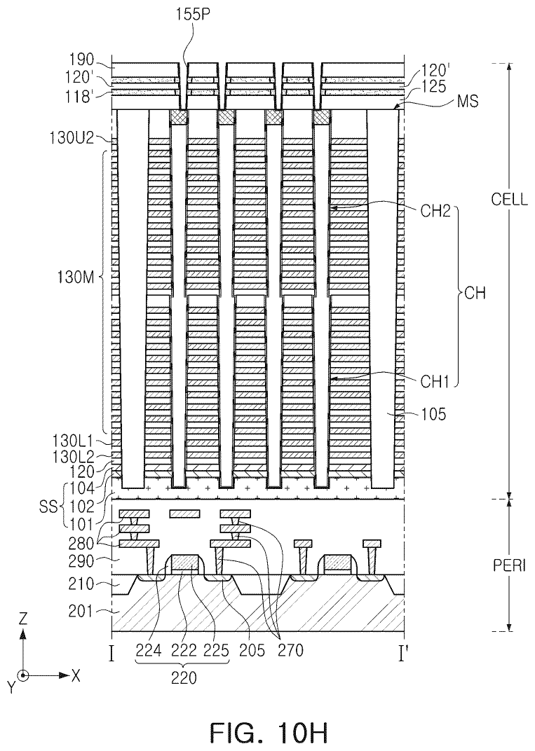

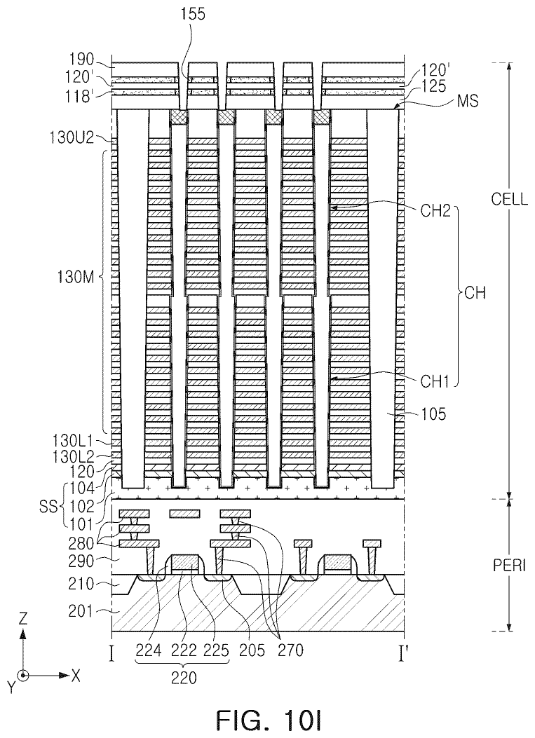

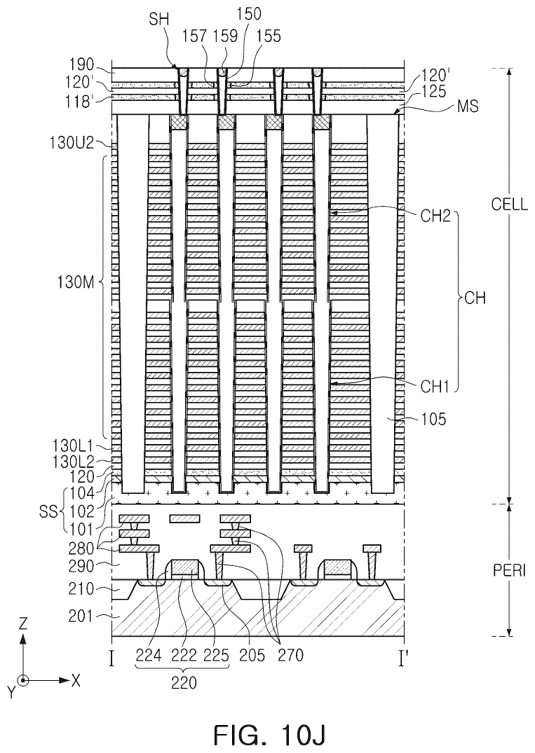

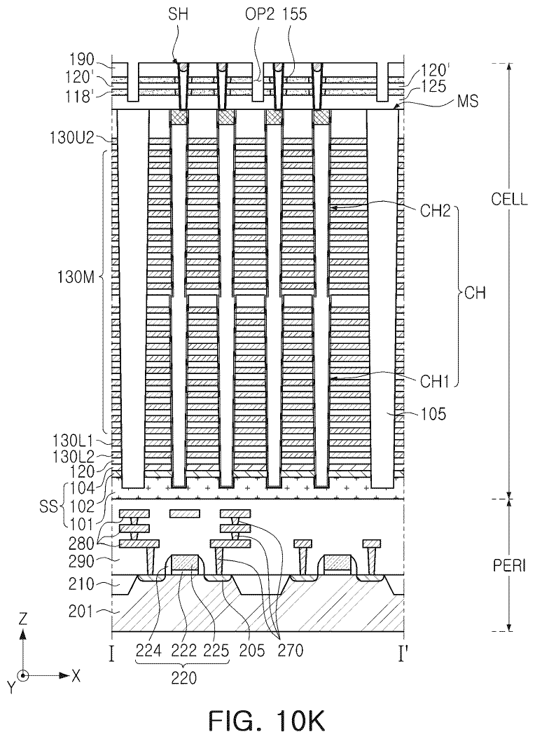

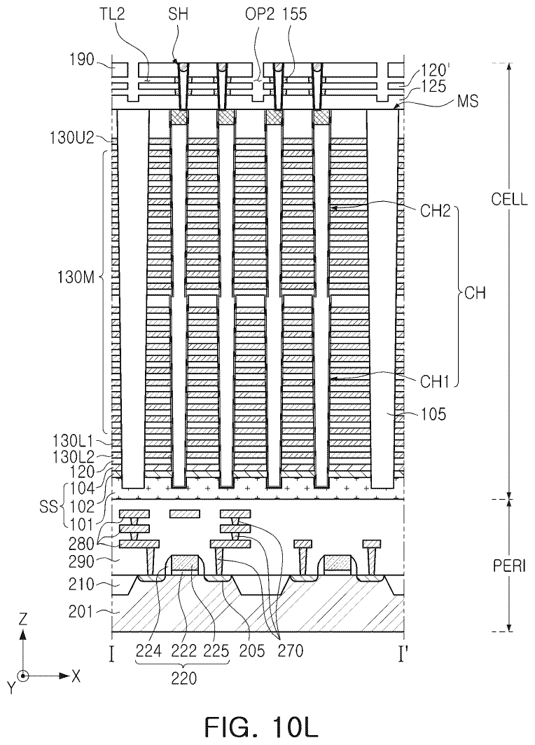

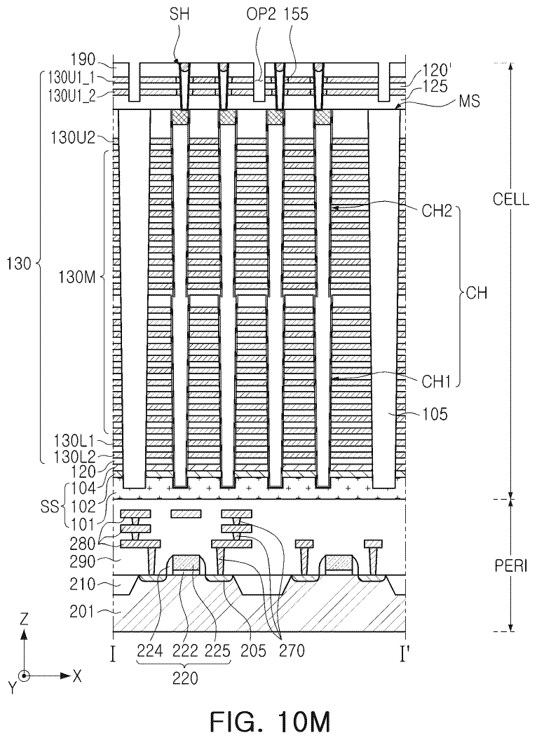

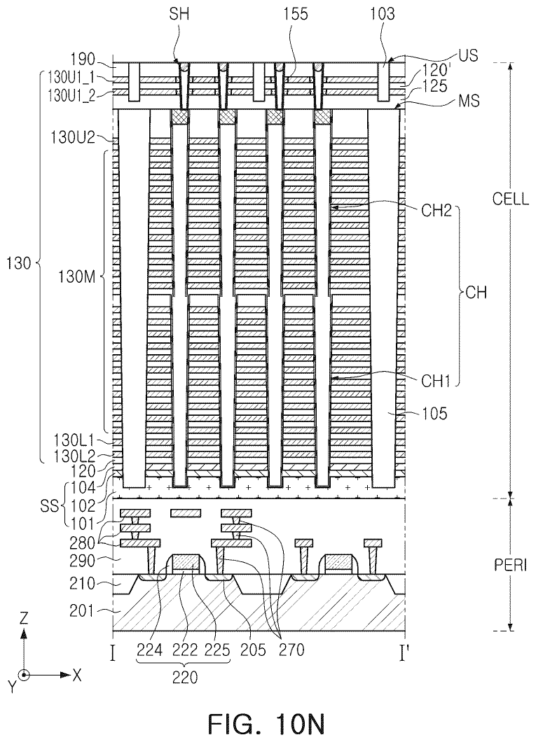

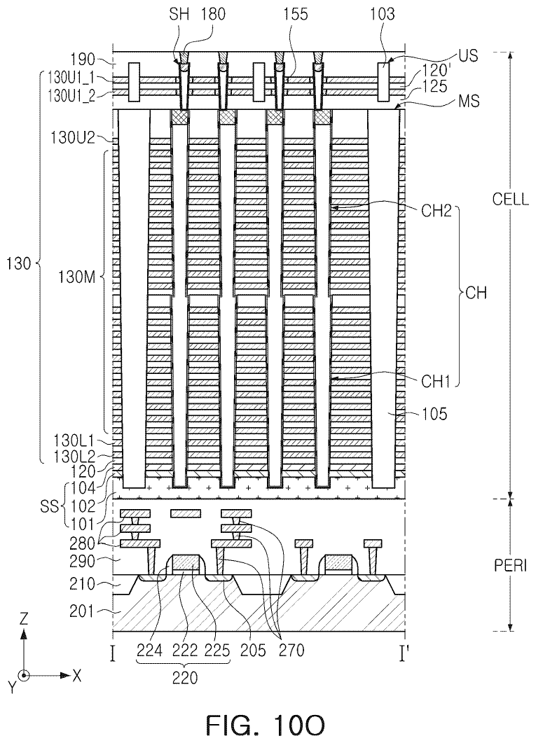

Referring to FIG. 4A, in a semiconductor device 100a, each of upper gate dielectric layers 155a may include first and second dielectric layers 155_1 and 155_2. The first and second dielectric layers 155_1 and 155_2 may be sequentially stacked on an external sidewall of a stud hole or an external side surface of an upper channel layer 150. The first dielectric layer 155_1 and the second dielectric layer 155_2 may include different materials. For example, the first dielectric layer 155_1 may include oxide (SiO₂) or silicon oxynitride (SiON), and the second dielectric layer 155_2 may include silicon nitride (SiN), however example embodiments are not limited thereto. For example, the first dielectric layer 155_1 may be an oxidation layer formed during a manufacturing process described below with reference to FIG. 10L, but example embodiments are not limited thereto. In some example embodiments, the upper gate dielectric layer 155a may include three or more layers including different materials.

Referring to FIG. 4B, in a semiconductor device 100b, upper gate dielectric layers 155b may be spaced apart from a sidewall of a stud hole in which a stud structure SH is disposed by a predetermined or dynamically determined length L2.

During the manufacturing process described below with reference to FIG. 10I, the upper gate dielectric layer 155b may be partially recessed from the stud hole. Accordingly, an external side surface of the upper channel layer 150b may also have a protruding region corresponding to the upper gate dielectric layers 155b. In some example embodiments, the length L2 of each of the upper gate dielectric layers 155b being recessed from the sidewall of the stud hole may be changed in various manners.

Referring to FIG. 4C, in a semiconductor device 100c, an upper gate dielectric layer 155c may extend onto an internal sidewall of a stud hole in which a stud structure SH is disposed.

The upper gate dielectric layer 155c may extend from a region in contact with first upper gate electrodes 130U1_1 and 130U1_2 into the stud hole, may cover the internal side wall of the stud hole, and may extend toward a bottom surface of the stud hole. In this case, the upper gate dielectric layer 155c may be disposed as a single layer. A thickness of the upper gate dielectric layer 155c between the first upper gate electrodes 130U1_1 and 130U1_2 and an upper channel layer 150 may be greater than a thickness of the upper gate dielectric layer 155c on the internal sidewall of the stud hole.

The upper gate dielectric layer 155c may have the above-described shape, for example, by performing a process operation described with reference to FIG. 10H and directly forming the upper channel layer 150, without performing a process operation described below with reference to FIG. 10I.

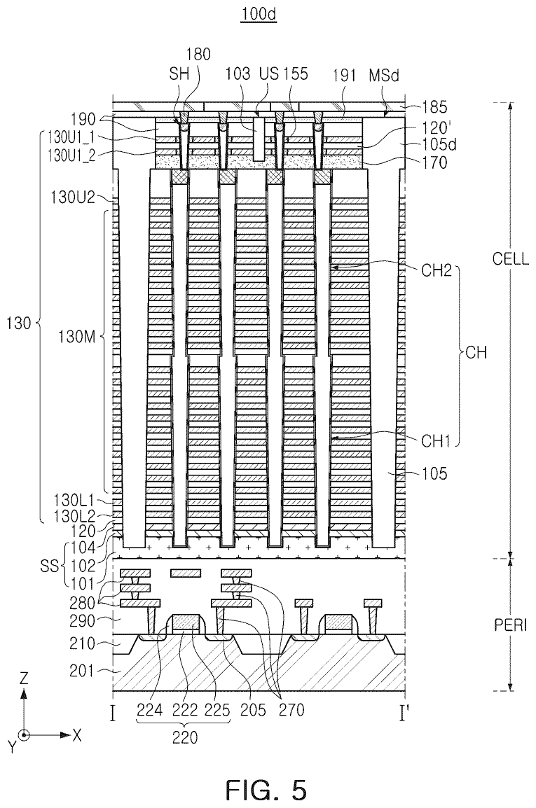

FIG. 5 is a schematic cross-sectional view of a semiconductor device according to various example embodiments. FIGS. 5 to 7 each illustrate a region corresponding to that of FIG. 2.

Referring to FIG. 5, in a semiconductor device 100d, a memory cell region CELL may further include a supporter 170 and a pad insulating layer 191 disposed on channel structures CH. In some regions, lower isolation regions MSd may be disposed to pass through entire gate electrodes 130.

The supporter 170 may be disposed on the channel structures CH and may have a plurality of openings disposed on the channel structures CH and spaced apart from each other in a Y-direction along lower isolation regions MSd on the lower isolation regions MSd. FIG. 5 illustrates regions of the supporter 170 respectively having openings on the lower isolation regions MSd. The lower isolation regions MSd may fill the openings in regions corresponding to the openings and may extend upward. The supporter 170 may be formed of an insulating material, and may include, for example, at least one of silicon oxide, silicon nitride, and silicon oxynitride, however example embodiments are not limited thereto. The supporter 170 may be formed of a material the same as or different from that of a cell region insulating layer 190.

The lower isolation regions MSd may have a bent portion having an increasing width in regions corresponding to the openings of the supporter 170. The bent portion may be formed according to a level of an upper surface of each of the channel structures CH. However, in some example embodiments, a shape of the bent portion may be changed in various manners. For example, in some example embodiments, the bent portion may have a decreasing width. An uppermost surface of each of the lower isolation regions MSd may be positioned on a level higher than that of an upper surface of each of the stud structures SH. The uppermost surface of each of the lower isolation regions MSd may be positioned on a level substantially the same as that of the upper surface of the pad insulating layer 191. However, when the gate isolation insulating layer 105, the cell region insulating layer 190, and the pad insulating layer 191 include the same material, interfaces therebetween may not be recognized. In the regions corresponding to the openings of the supporter 170, the upper isolation region US may be integrated with the lower isolation regions MSd without being additionally disposed on the lower isolation regions MSd. The lower isolation regions MSd may have a shape the same as that of FIG. 2 in regions not corresponding to the openings of the supporter 170.

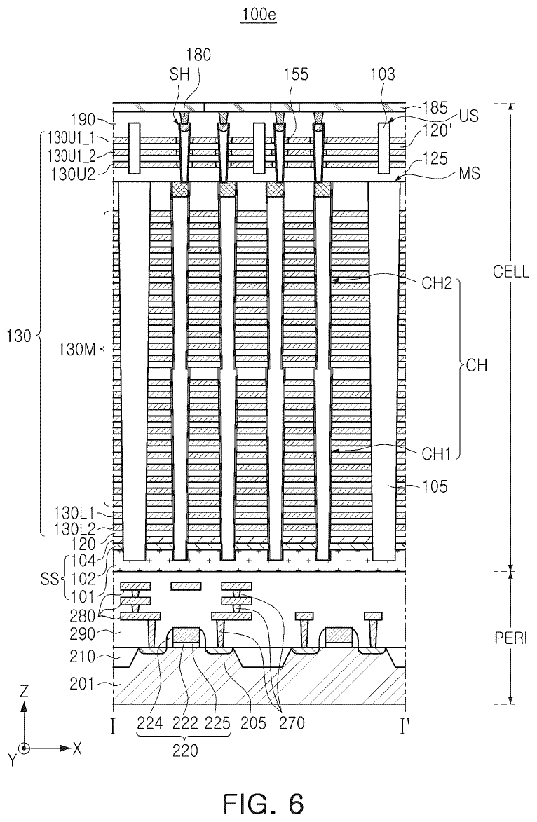

Referring to FIG. 6, in a semiconductor device 100e, stud structures SH may be disposed to further pass through a second upper gate electrode 130U2 in addition to first upper gate electrodes 130U1_1 and 130U1_2.

The second upper gate electrode 130U2 may be a gate electrode forming an erase transistor, and may be used for an erase operation using a gate induced drain leakage (GIDL) phenomenon. In various example embodiments, the number of gate electrodes, forming the second upper gate electrode 130U2, may be changed in various manners. In some example embodiments, the second upper gate electrode 130U2 may be disposed on the first upper gate electrodes 130U1_1 and 130U1_2.

As described above, in some example embodiments, among gate electrodes 130 disposed on a memory gate electrode 130M, the number of gate electrodes 130 through which stud structures SH pass may be changed in various manners. In some example embodiments, the gate electrodes 130 may further include a dummy gate electrode disposed on and/or below the second upper gate electrode 130U2, and the stud structures SH may be disposed to further pass through the dummy gate electrode.

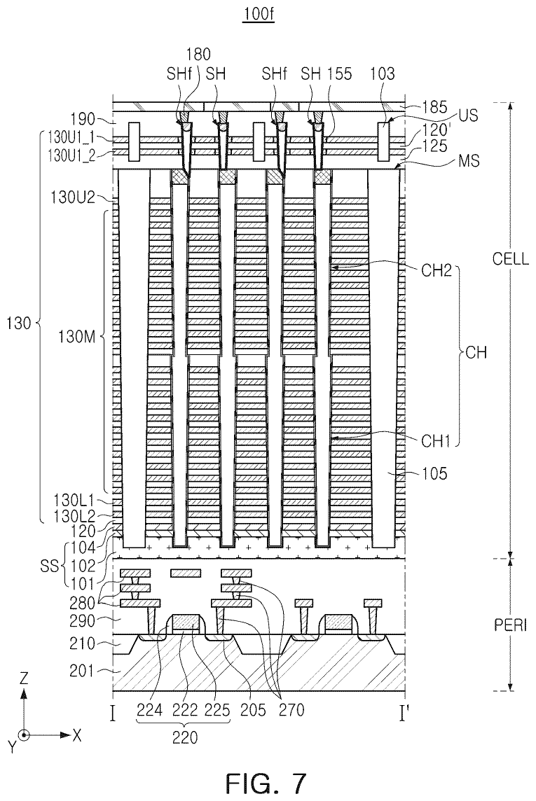

Referring to FIG. 7, in a semiconductor device 100f, some stud structures SHf may be misaligned with channel structures CH.

At least some stud structures SHf, among stud structures SH and SHf, may be formed to downwardly extend along one side of the channel structures CH. The stud structures SHf may have an asymmetrical shape with respect to the central axis thereof. However, in some example embodiments, a length and shape of each of the stud structures SHf downwardly extending may be changed in various manners. The stud structures SHf may also be misaligned with the cell contact plugs 180.

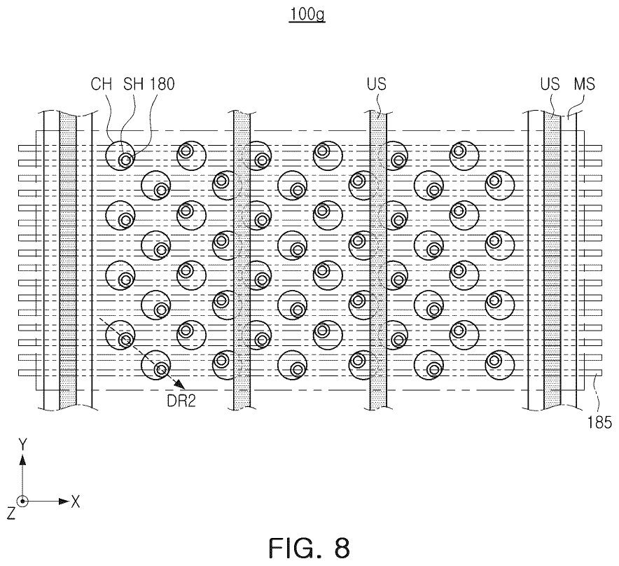

FIG. 8 is a schematic plan view of a semiconductor device according to some example embodiments.

Referring to FIG. 8, in a semiconductor device 100g, with respect to channel structures CH, twelve channel structures CH may be disposed to have a zigzag shape in an X-direction between adjacent lower isolation regions MS, and may be repeatedly disposed to have the above-described shape.

Two upper isolation regions US may be disposed between the adjacent lower isolation regions MS in the X-direction. Stud structures SH may be disposed to be shifted from the channel structures CH in a second horizontal direction DR2. The second horizontal direction DR2 may be a diagonal direction along the arrangement of the channel structures CH, and may be a direction inclined with respect to the X-direction and a Y-direction.

As described above, in some example embodiments, between the lower isolation regions MS, the arrangement of the channel structures CH, the stud structures SH, and the upper isolation regions US may be changed in various manners.

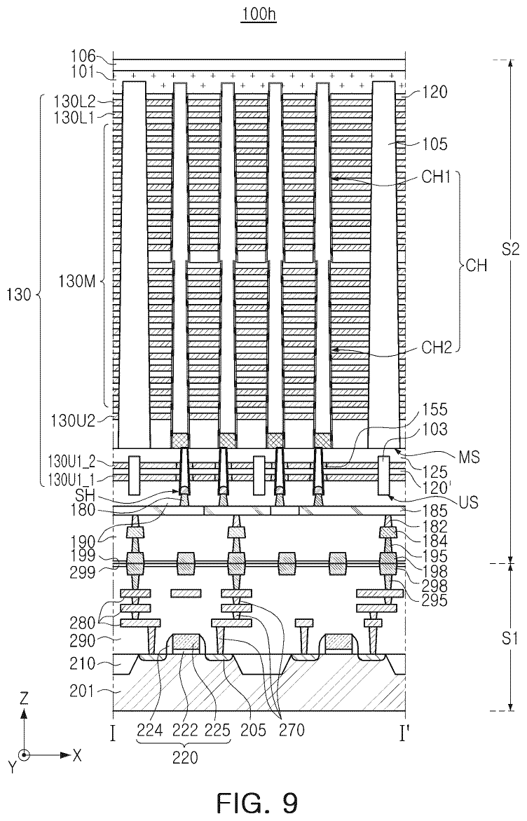

FIG. 9 is a schematic cross-sectional view of a semiconductor device according to some example embodiments. FIG. 9 illustrates a region corresponding to that of FIG. 2.

Referring to FIG. 9, a semiconductor device 100h may include a first semiconductor structure S1 and a second semiconductor structure S2 bonded to each other using a wafer bonding method.

The description of a peripheral circuit region PERI described above with reference to FIGS. 1 to 3B may be applied to the first semiconductor structure S1. However, the first semiconductor structure S1 may further include first bonding vias 295, first bonding metal layers 298, and a first bonding insulating layer 299, which are bonding structures. The first bonding vias 295 may be disposed on upper portions of uppermost circuit interconnection lines 280 to be connected to the circuit interconnection lines 280. At least a portion of the first bonding metal layers 298 may be connected to the first bonding vias 295 on the first bonding vias 295. The first bonding metal layers 298 may be connected to second bonding metal layers 198 of the second semiconductor structure S2. The bonding metal layers 298 may provide an electrical connection path according to bonding of the first semiconductor structure S1 and the second semiconductor structure S2, together with the second bonding metal layers 198. A portion of the first bonding metal layers 298 may be disposed only for bonding without being connected to lower circuit interconnection lines 280. The first bonding vias 295 and the first bonding metal layers 298 may include a conductive material, such as copper (Cu). The first bonding insulating layer 299 may be disposed on circumferences of the first bonding metal layers 298. The first bonding insulating layer 299 may also function as a diffusion barrier of each of the first bonding metal layers 298, and may include, for example, at least one of SiN, SiON, SiCN, SiOC, SiOCN, and SiO, however example embodiments are not limited thereto.

Unless otherwise described, the description of the memory cell region CELL described above with reference to FIGS. 1 to 3B may be applied to the second semiconductor structure S2. The second semiconductor structure S2 may further include lower contact plugs 182 and cell interconnection lines 184, which are cell interconnection structures, and may further include second bonding vias 195, second bonding metal layers 198, and a second bonding insulating layer 199, which are bonding structures. The second semiconductor structure S2 may further include a passivation layer 106, covering an upper surface of the plate layer 101. The second semiconductor structure S2 may not include the first and second horizontal conductive layers 102 and 104 on a lower surface of the plate layer 101, differently from the example embodiment in FIG. 2, and the lower channel layer 140 may directly contact the plate layer 101 at an upper end of the lower channel layer 140.

The lower contact plugs 182 may be connected to bit lines 185, and the cell interconnection lines 184 may be connected to the lower contact plugs 182. However, in further example embodiments, the number of layers and the arrangement of contact plugs and interconnection lines, forming a cell interconnection structure, may be changed in various manners. The lower contact plugs 182 and the cell interconnection lines 184 may be formed of a conductive material, and may include, for example, at least one of tungsten (W), aluminum (Al), and copper (Cu), however example embodiments are not limited thereto.

The second bonding vias 195 and the second bonding metal layers 198 may be disposed below lowermost cell interconnection lines 184. The second bonding vias 195 may connect the cell interconnection lines 184 and the second bonding metal layers 198 to each other, and the second bonding metal layers 198 may be bonded to the first bonding metal layers 298 of the first semiconductor structure S1. The second bonding insulating layer 199 may be bonded and connected to the first bonding insulating layer 299 of the first semiconductor structure S1. The second bonding vias 195 and the second bonding metal layers 198 may include a conductive material, such as copper (Cu). The second bonding insulating layer 199 may include, for example, at least one of silicon oxide (SiO), silicon nitride (SiN), silicon carbon nitride (SiCN), silicon oxycarbide (SiOC), silicon oxynitride (SiON), and silicon oxycarbonitride (SiOCN), however example embodiments are not limited thereto.

The first and second semiconductor structures S1 and S2 may be bonded to each other by bonding between the first bonding metal layers 298 and the second bonding metal layers 198 and bonding between the first bonding insulating layer 299 and the second bonding insulating layer 199. The bonding between the first bonding metal layers 298 and the second bonding metal layers 198 may be, but is not limited to, for example, copper (Cu)-to-copper (Cu) bonding. The bonding between the first bonding insulating layer 299 and the second bonding insulating layer 199 may be dielectric-to-dielectric bonding, such as, but is not limited to, SiCN-to-SiCN bonding, for example. The first and second semiconductor structures S1 and S2 may be bonded to each other by hybrid bonding including copper (Cu)-to-copper (Cu) bonding and dielectric-to-dielectric bonding.

The passivation layer 106 may be disposed on an upper surface of the plate layer 101 and may protect the semiconductor device 100h. The passivation layer 106 may include an insulating material, for example, at least one of silicon oxide, silicon nitride, silicon oxynitride, and silicon carbide, and may be formed of a plurality of insulating layers, however example embodiments are not limited thereto.

FIGS. 10A to 10O are schematic cross-sectional views illustrating a method of manufacturing a semiconductor device according to some example embodiments. FIGS. 10A to 10O each illustrate a region corresponding to that of FIG. 2.

Referring to FIG. 10A, circuit elements 220 forming a peripheral circuit region PERI, a circuit interconnection structure, and a peripheral region insulating layer 290 may be formed on a substrate 201.

In various example embodiments, element isolation layers 210 may be formed in the substrate 201, and a circuit gate dielectric layer 222 and a circuit gate electrode 225 may be sequentially formed on the substrate 201. The element isolation layers 210 may be formed using, for example, a shallow trench isolation (STI) process, spin on dielectric (SOD), air gap isolation, or the like, however example embodiments are not limited thereto. The circuit gate dielectric layer 222 and the circuit gate electrode 225 may be formed using an atomic layer deposition (ALD) process or chemical vapor deposition (CVD) process, however example embodiments are not limited thereto. The circuit gate dielectric layer 222 may be formed of silicon oxide, and the circuit gate electrode 225 may be formed of at least one of polycrystalline silicon or a metal silicide layer, but example embodiments are not limited thereto. Subsequently, a spacer layer 224 and impurity regions 205 may be formed on both sidewalls of the circuit gate dielectric layer 222 and the circuit gate electrode 225. In some example embodiments, the spacer layer 224 may be formed of a plurality of layers. Subsequently, the impurity regions 205 may be formed by performing an ion implantation, diffusion, or plasma doping process, however example embodiments are not limited thereto.

Circuit contact plugs 270 of the circuit interconnection structure may be formed by forming a portion of the peripheral region insulating layer 290, etching and removing the portion, and filling the removed portion with a conductive material. The circuit interconnection lines 280 may be formed by, for example, depositing a conductive material and then patterning the deposited conductive material. However, example embodiments are not limited to the formation processes thereof.

The peripheral region insulating layer 290 may be formed of a plurality of insulating layers. The peripheral region insulating layer 290 may be a portion in respective operations of forming the circuit interconnection structure. As a result, the peripheral circuit region PERI may be formed.

Referring to FIG. 10B, a plate layer 101 provided with a memory cell region CELL, a horizontal insulating layer 110, and a second horizontal conductive layer 104 may be formed on the peripheral circuit region PERI, and lower sacrificial insulating layers 118 and lower interlayer insulating layers 120 may be alternately stacked to form a lower mold structure, and lower channel sacrificial layers 119 may be formed to form an upper mold structure.

The plate layer 101 may be formed on the peripheral insulating layer 290. The plate layer 101 may be formed of, for example, polycrystalline silicon, or the like, and may be formed using the CVD process, however example embodiments are not limited thereto. Polycrystalline silicon, forming the plate layer 101, may include impurities.

First and second horizontal insulating layers 111 and 112, forming the horizontal insulating layer 110, may be alternately stacked on the plate layer 101. The horizontal insulating layer 110 may be replaced with the first horizontal conductive layer 102 of FIG. 2 through a subsequent process. The first horizontal insulating layers 111 may include a material different from that of the second horizontal insulating layer 112. For example, the first horizontal insulating layers 111 may be formed of a material the same as that of the lower interlayer insulating layers 120, and the second horizontal insulating layer 112 may be formed of a material the same as that of the lower sacrificial insulating layers 118. The second horizontal conductive layer 104 may be formed on the horizontal insulating layer 110.

The lower mold structure may be formed on the second horizontal conductive layer 104 at a height at which the first channel structures CH1 (see FIG. 2) of the channel structures CH (see FIG. 2) are disposed.

The lower sacrificial insulating layers 118 may be replaced with a portion of the gate electrodes 130 (see FIG. 2) through a subsequent process. The lower sacrificial insulating layers 118 may be formed of a material different from that of the lower interlayer insulating layers 120, and may be formed of a material that may be etched with etch selectivity with respect to the lower interlayer insulating layers 120 under specific etching conditions. For example, the lower interlayer insulating layer 120 may be formed of at least one of silicon oxide and silicon nitride, and the lower sacrificial insulating layers 118 may be formed of a material different from that of the lower interlayer insulating layer 120 selected from among silicon, silicon oxide, silicon carbide, and silicon nitride. In various example embodiments, the lower interlayer insulating layers 120 may not all have the same thickness. Thicknesses of the lower interlayer insulating layers 120 and the lower sacrificial insulating layers 118 and the number of films, forming the lower interlayer insulating layers 120 and the lower sacrificial insulating layers 118, may be changed in various manners from those illustrated.

The lower channel sacrificial layers 119 may be formed in positions corresponding to those of the first channel structures CH1. The lower channel sacrificial layers 119 may be formed by forming lower channel holes to pass through the lower mold structure, depositing a material forming the lower channel sacrificial layers 119 in the lower channel holes, and performing a planarization process thereon. The lower channel sacrificial layers 119 may include, for example, polycrystalline silicon, silicon oxide, or the like, however example embodiments are not limited thereto.

The upper mold structure may be formed on the lower mold structure at a height at which the second channel structures CH2 (see FIG. 2) of the channel structures CH are disposed. The upper mold structure may be formed by alternately stacking the lower sacrificial insulating layers 118 and the lower interlayer insulating layers 120 in the same manner as the lower mold structure.

Referring to FIG. 10C, the channel structures CH, passing through the lower mold structure and the upper mold structure, may be formed.

First, upper channel sacrificial layers, passing through the upper mold structure, may be formed. The upper channel sacrificial layers may be formed in positions corresponding to those of upper channel structures CH2. The upper channel sacrificial layers may be formed to be connected to the lower channel sacrificial layers 119, respectively.

The channel structures CH may be formed by removing the lower channel sacrificial layers 119 and the upper channel sacrificial layers to form channel holes in the form of a hole, and then sequentially depositing at least a portion of a lower gate dielectric layer 145, a lower channel layer 140, a lower filling insulating layer 147, and a lower pad 149 in the channel holes.

The lower gate dielectric layer 145 may be formed to have a uniform thickness using the ALD or CVD process, however example embodiments are not limited thereto. In various example embodiments, all of or a portion of the lower gate dielectric layer 145 may be formed, and a portion of the lower gate dielectric layer 145, extending to be perpendicular to the plate layer 101 along the channel structures CH, may be formed in some example embodiments. The lower channel layer 140 may be formed on the lower gate dielectric layer 145 in the channel holes. The lower filling insulating layer 147 may be formed to fill the channel holes, and may be formed of an insulating material. The lower pad 149 may be formed of a conductive material, for example, polycrystalline silicon, or the like, however example embodiments are not limited thereto.

Referring to FIG. 10D, first openings OP1 may be formed, a first horizontal conductive layer 102 may be formed, and the lower sacrificial insulating layers 118 may be removed.

The first openings OP1 may be formed in positions of the lower isolation regions MS (see FIG. 2). The first openings OP1 may be formed to extend to the plate layer 101 through the lower sacrificial insulating layers 118 and the lower interlayer insulating layers 120. An etch-back process may be performed while additional sacrificial spacer layers are formed in the first openings OP1 to selectively remove the horizontal insulating layer 110 and to also remove a portion of the exposed lower gate dielectric layer 145 together with the horizontal insulating layer 110. After the first horizontal conductive layer 102 is formed by depositing a conductive material in a region in which the horizontal insulating layer 110 is removed, the sacrificial spacer layers may be removed in the first openings OP1.

The lower sacrificial insulating layers 118 may be selectively removed with respect to the lower interlayer insulating layers 120, the second horizontal conductive layer 104, and the channel structures CH using, for example, wet etching. First tunnel portions TL1 may be formed in region in which the lower sacrificial insulating layers 118 are removed.

Referring to FIG. 10E, a second lower gate electrode 130L2, a first lower gate electrode 130L1, memory gate electrodes 130M, and a second upper gate electrode 130U2 may be formed, and the lower isolation regions MS may be formed.

In various example embodiments, among gate electrodes 130, first gate electrodes surrounding the channel structures CH, for example, the second lower gate electrode 130L2, the first lower gate electrode 130L1, the memory gate electrodes 130M, and the second upper gate electrode 130U2 may be formed. The first gate electrodes may be formed by depositing a conductive material on the first tunnel portions TL1. As illustrated in FIG. 3B, the first gate electrodes may include a gate barrier layer 132 and a gate conductive layer 135. In some example embodiments, a portion of the lower gate dielectric layer 145 may be first formed before the first gate electrodes are formed. After the first gate electrodes are formed, gate isolation insulating layers 105 may be formed in the first openings OP1 to form the lower isolation regions MS.

Referring to FIG. 10F, an uppermost mold structure may be formed on the channel structures CH, and stud holes SHH, passing through the uppermost mold structure, may be formed.

The uppermost mold structure may be formed by forming an intermediate insulating layer 125 on the channel structures CH and alternately stacking upper sacrificial insulating layers 118′ and upper interlayer insulating layers 120′. The description of the lower sacrificial insulating layers 118 and the lower interlayer insulating layers 120 described above may be applied to materials of the upper sacrificial insulating layers 118′ and the upper interlayer insulating layers 120′ in the same manner. A portion of a cell region insulating layer 190 may be formed on an uppermost sacrificial insulating layer 118′.

The stud holes SHH may pass through the uppermost mold structure to expose the channel structures CH.

Referring to FIG. 10G, a portion of the upper sacrificial insulating layers 118′, exposed through the stud holes SHH, may be removed.

A portion of the upper sacrificial insulating layers 118′, exposed through the stud holes SHH, may be selectively removed with respect to the upper interlayer insulating layers 120′. Accordingly, the upper sacrificial insulating layers 118′ may be horizontally recessed from the stud holes SHH.

Referring to FIG. 10H, a preliminary upper gate dielectric layer 155P may be formed in the stud holes SHH. The preliminary upper gate dielectric layer 155P may fill recessed regions of the upper sacrificial insulating layers 118′, and may cover internal sidewalls of the stud holes SHH.

Referring to FIG. 10I, upper gate dielectric layers 155 may be formed by removing the preliminary upper gate dielectric layer 155P on internal sidewalls of the stud holes SHH.

The preliminary upper gate dielectric layer 155P may form the upper gate dielectric layers 155 by remaining only in regions in which the upper sacrificial insulating layers 118′ are recessed. The upper gate dielectric layers 155 may be disposed on external sidewalls of the stud holes SHH to outwardly protrude from the stud holes SHH.

Referring to FIG. 10J, the stud structures SH may be formed by sequentially forming an upper channel layer 150, an upper filling insulating layer 157, and an upper pad 159 in the stud holes SHH, respectively.

The upper channel layer 150 may be formed to cover an internal sidewall of the stud hole SHH. A lower end of the upper channel layer 150 may be connected to the lower pad 149 (see FIG. 10C) and/or the lower channel layer 140 (see FIG. 10C) of the channel structure CH. The upper filling insulating layer 157 may be formed to fill the stud hole SHH. The upper pad 159 may be formed by removing a portion of the upper filling insulating layer 157 from an upper portion of the stud hole SHH and then filling a conductive layer, for example, polycrystalline silicon, or the like, however example embodiments are not limited thereto. As a result, the stud structures SH including the upper channel layer 150, the upper filling insulating layer 157, and the upper pad 159 may be formed.

Referring to FIG. 10K, second openings OP2, passing through a portion of the uppermost mold structure, may be formed.

The second openings OP2 may be formed to pass through the upper sacrificial insulating layers 118′ in regions corresponding to the upper isolation regions US of FIG. 2. Lower ends of the second openings OP2 may be positioned in the intermediate insulating layer 125.

Referring to FIG. 10L, the upper sacrificial insulating layers 118′ may be removed through the second openings OP2.

The upper sacrificial insulating layers 118′ may be selectively removed with respect to the upper interlayer insulating layers 120′, the intermediate insulating layer 125, and the upper gate dielectric layers 155 using, for example, wet etching. Second tunnel portions TL2 may be formed in regions in which the upper sacrificial insulating layers 118′ are removed.

Referring to FIG. 10M, first upper gate electrodes 130U1_1 and 130U1_2 may be formed.

In various example embodiments, among the gate electrodes 130, second gate electrodes surrounding the stud structures SH, for example, the first upper gate electrodes 130U1_1 and 130U1_2 may be formed. The second gate electrodes may be formed by depositing a conductive material on the second tunnel portions TL2. As illustrated in FIG. 3A, the second gate electrodes may include a gate barrier layer 132 and a gate conductive layer 135.

Referring to FIG. 10N, upper isolation regions US may be formed. The upper isolation regions US may be formed by forming upper isolation insulating layers 103 in the second openings OP2.

Referring to FIG. 10O, cell contact plugs 180 may be formed on the stud structures SH. First, after the cell region insulating layer 190 is further formed, a portion of the cell region insulating layer 190 may be removed and a conductive material may be deposited to form the cell contact plugs 180.

Subsequently, referring FIG. 10O to together with FIG. 2, the semiconductor device 100 of FIG. 2 may be formed by forming bit lines 185 on the cell contact plugs 180.

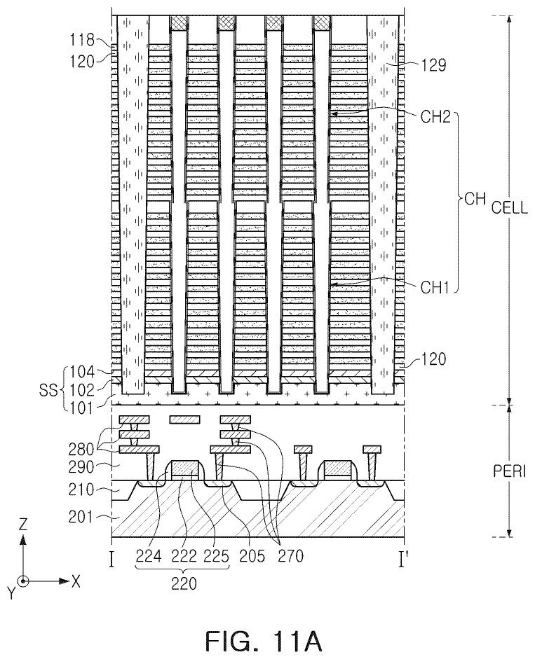

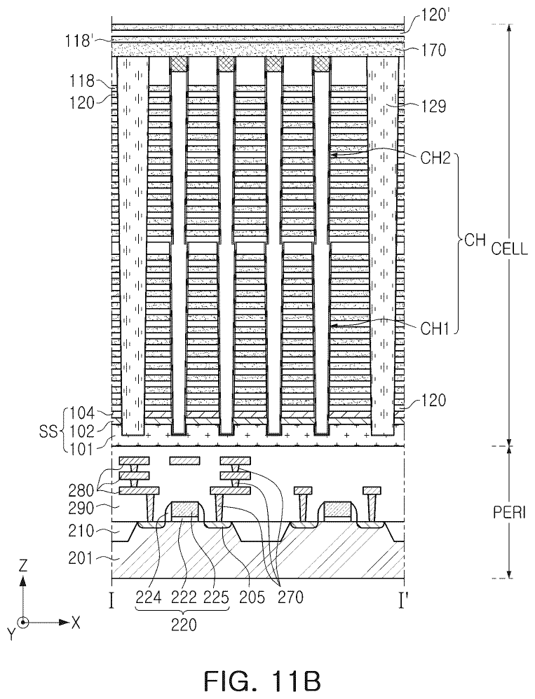

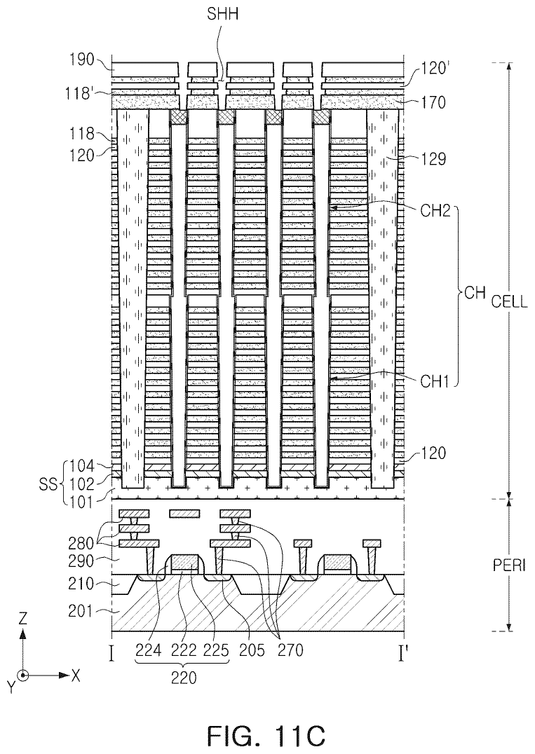

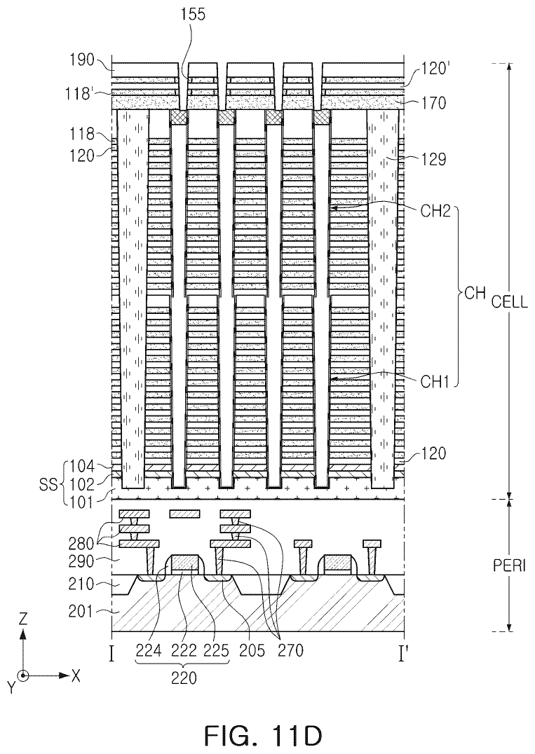

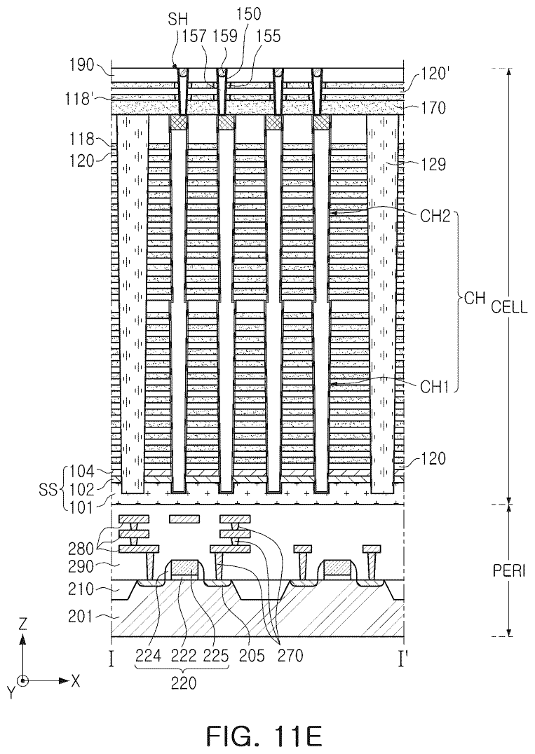

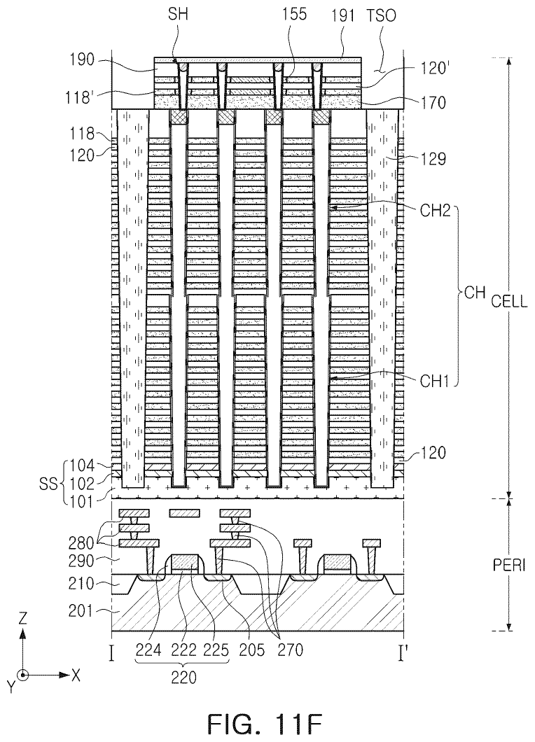

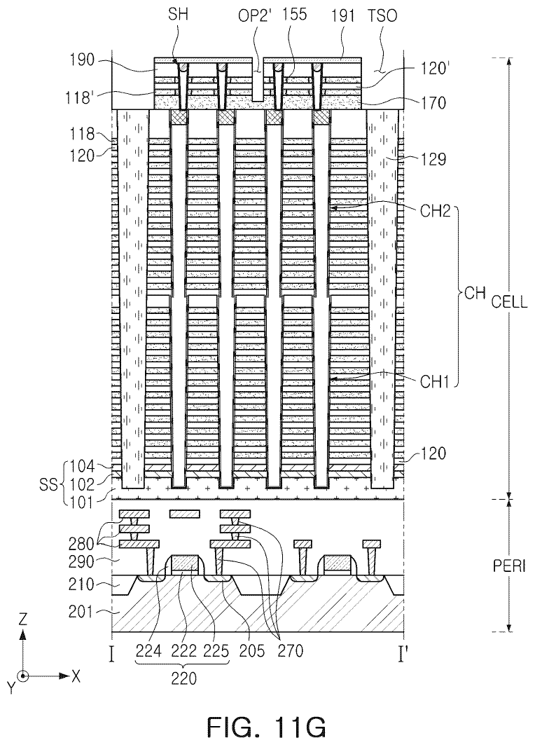

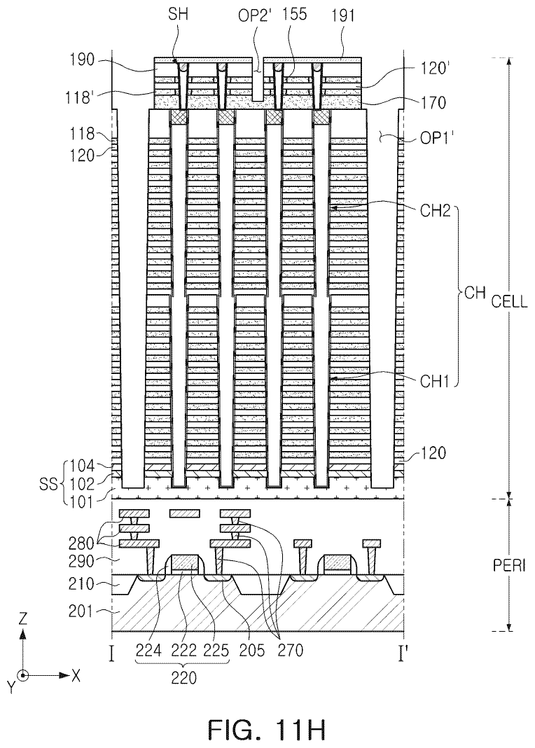

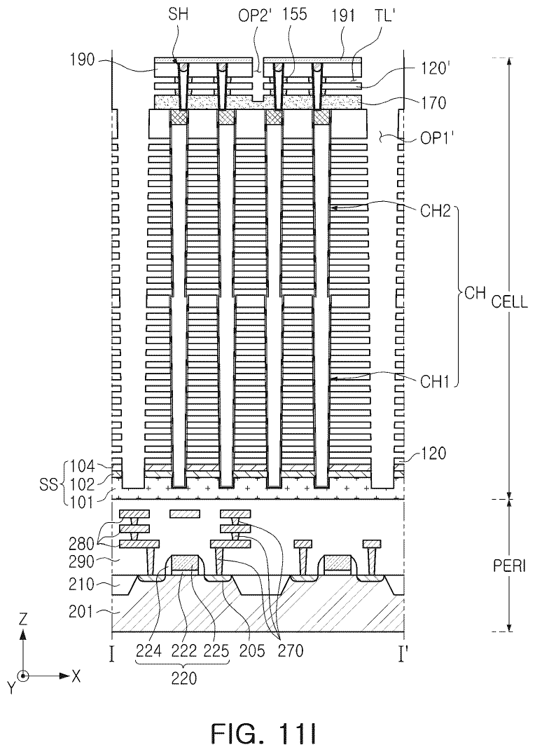

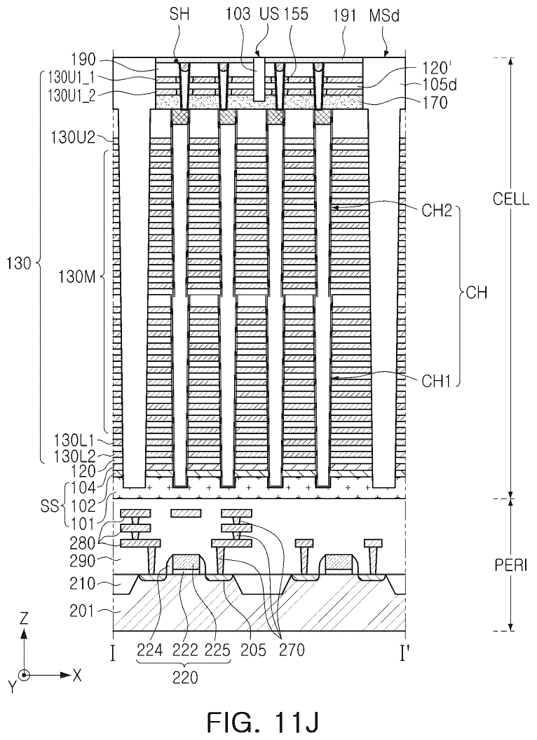

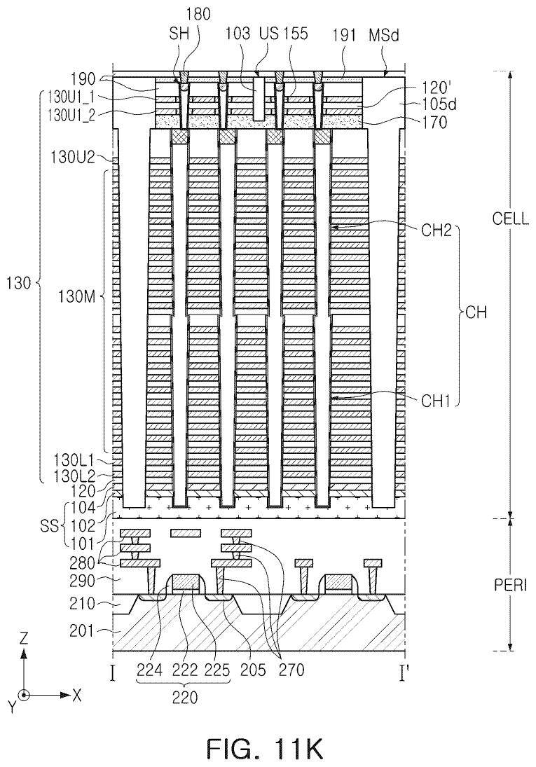

FIGS. 11A to 11K are schematic cross-sectional views illustrating a method of manufacturing a semiconductor device according to some example embodiments. FIGS. 11A to 11K each illustrate a region corresponding to that of FIG. 5.

Referring to FIG. 11A, a peripheral circuit region PERI may be formed, lower sacrificial insulating layers 118 and lower interlayer insulating layers 120 may be alternately stacked, channel structures CH may be formed, a first horizontal conductive layer 102 may be formed, and vertical sacrificial layers 129 may be formed.

First, the process described above with reference to FIGS. 10A to 10C may be performed in the same manner to form the peripheral circuit region PERI, a plate layer 101, a horizontal insulating layer 110, a second horizontal conductive layer 104, a lower mold structure, an upper mold structure, and channel structures CH.

After openings are formed in positions of the lower isolation regions MS (see FIG. 2), the first horizontal conductive layer 102 may be formed, and vertical sacrificial layers 129 may be formed. The first horizontal conductive layer 102 may be formed as described above with reference to FIG. 10D. The vertical sacrificial layers 129 may be formed to fill the openings. The vertical sacrificial layers 129 may be formed of a single layer or a plurality of layers. For example, the vertical sacrificial layers 129 may include a double layer formed of silicon nitride/polycrystalline silicon.

Referring to FIG. 11B, supporters 170 may be formed on the channel structures CH, and an uppermost mold structure may be formed.

A supporter 170 may be a layer for supporting a stack structure of the lower interlayer insulating layers 120 during a subsequent process of removing the lower sacrificial insulating layers 118. The supporter 170 may be formed not to have an opening in some example embodiments.

The uppermost mold structure may be formed by alternately stacking upper sacrificial insulating layers 118′ and upper interlayer insulating layers 120′ on the supporter 170.

Referring to FIG. 11C, stud holes SHH, passing through the upper mold structure, may be formed, and a portion of the upper sacrificial insulating layers 118′, exposed through the stud holes SHH, may be removed.

First, a portion of a cell region insulating layer 190 may be formed on an uppermost sacrificial insulating layer 118′. The stud holes SHH may be formed to pass through the uppermost mold structure and expose the channel structures CH.

A portion of the upper sacrificial insulating layers 118′, exposed through the stud holes SHH, may be selectively removed with respect to the upper interlayer insulating layers 120′. Accordingly, the upper sacrificial insulating layers 118′ may be recessed from the stud holes SHH.

Referring to FIG. 11D, upper gate dielectric layers 155 may be formed on external sidewalls of the stud holes SHH.

First, as described above with reference to FIG. 10H, a preliminary upper gate dielectric layer 155P may be formed, and then the preliminary upper gate dielectric layer 155P may be removed on internal sidewalls of the stud holes SHH. Accordingly, the upper gate dielectric layer 155P may remain only in regions in which the upper sacrificial insulating layers 118′ are recessed to form the upper gate dielectric layers 155.

Referring to FIG. 11E, the stud structures SH may be formed by sequentially forming an upper channel layer 150, an upper filling insulating layer 157, and an upper pad 159 in the stud holes SHH, respectively. The stud structures SH may be formed using a process the same as that described above with reference to FIG. 10J.

Referring to FIG. 11F, a pad insulating layer 191 may be formed on the stud structures SH, and then supporter openings TSO may be formed.

The pad insulating layer 191 may be formed by depositing an insulating material. The supporter openings TSO may be formed to pass through the pad insulating layer 191, the uppermost mold structure, and the supporter 170. The support openings TSO may be formed on the vertical sacrificial layers 129 at regular intervals along the y direction. Vertical sacrificial layers 129 may be exposed through the support openings TSO.

In some example embodiments, the support openings TSO may be formed to recess upper portions of the vertical sacrificial layers 129. In some example embodiments, a width and depth of each of the support openings TSO may be changed in various manners.

Referring to FIG. 11G, a second opening OP2′, passing through a portion of the uppermost mold structure, may be formed.

The second opening OP2′ may be formed to pass through the upper sacrificial insulating layers 118′ in a region corresponding to the upper isolation region US of FIG. 5. A lower end of the second opening OP2′ may be positioned in the supporter 170.

Referring to FIG. 11H, first openings OP1′ may be formed by removing the vertical sacrificial layers 129. The vertical sacrificial layer 119, exposed through the supporter openings TSO, may be selectively removed to form the first openings OP1′ having a form in which the supporter openings TSO downwardly extend.

Referring to FIG. 11I, sacrificial insulating layers 118 and 118′ may be removed through the first openings OP1′.

The sacrificial insulating layers 118 and 118′ may be selectively removed with respect to, for example, the interlayer insulating layers 120 and 120′, the supporter 170, the cell region insulating layer 190, the pad insulating layer 191, and the upper gate dielectric layers 155. Tunnel portions TL′ may be formed in regions in which the sacrificial insulating layers 118 and 118′ are removed.

Referring to FIG. 11J, gate electrodes 130 may be formed by filling tunnel portions LT′ with a conductive material, and lower isolation regions MSd may be formed.

In various example embodiments, all of the gate electrodes 130 may be formed. The gate electrodes 130 may include a gate barrier layer 132 and a gate conductive layer 135, as illustrated in FIGS. 3A and 3B. After the gate electrodes 130 are formed, gate isolation insulating layers 105d may be formed in the first openings OP1′ to form lower isolation regions MSd.

Referring to FIG. 11K, cell contact plugs 180 may be formed on the stud structures SH. First, after the cell region insulating layer 190 is further formed, portions of the cell region insulating layer 190 and the pad insulating layer 191 may be removed and a conductive material may be deposited to form the cell contact plugs 180.

Subsequently, referring to FIG. 11K together with FIG. 5, the semiconductor device 100d of FIG. 5 may be formed by forming bit lines 185 on the cell contact plugs 180.

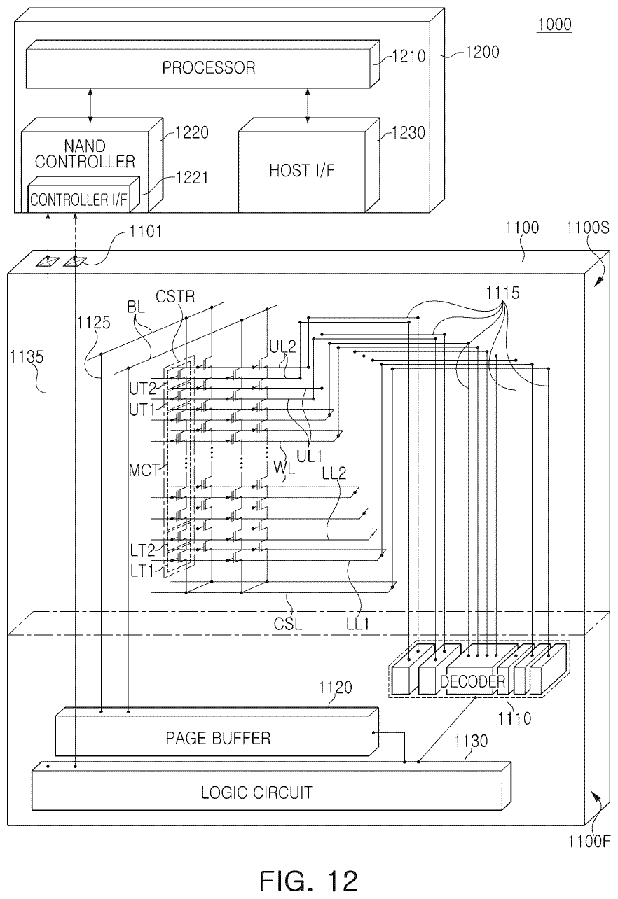

FIG. 12 is a schematic diagram illustrating a data storage system including a semiconductor device according to various example embodiments.

Referring to FIG. 12, a data storage system 1000 may include a semiconductor device 1100 and a controller 1200 electrically connected to the semiconductor device 1100. The data storage system 1000 may be a storage device including one or a plurality of semiconductor devices 1100 or an electronic device including the storage device. For example, the data storage system 1000 may be a solid-state drive device (SSD) including one or a plurality of semiconductor devices 1100, a universal serial bus (USB), a computing system, a medical device, or a communication device, however example embodiments are not limited thereto.

The semiconductor device 1100 may be a nonvolatile memory device, and may be, for example, the NAND flash memory device described above with reference to FIGS. 1 to 9. The semiconductor device 1100 may include a first structure 1100F and a second structure 1100S on the first structure 1100F. In various example embodiments, the first structure 1100F may be disposed next to the second structure 1100S. The first structure 1100F may be a peripheral circuit structure including a decoder circuit 1110, a page buffer 1120, and a logic circuit 1130. The second structure 1100S may be a memory cell structure including a bit line BL, a common source line CSL, word lines WL, first and second gate upper lines UL1 and UL2, first and second gate lower lines LL1 and LL2, and memory cell strings CSTR between the bit line BL and the common source line CSL.

In the second structure 1100S, each of the memory cell strings CSTR may include lower transistors LT1 and LT2 adjacent to the common source line CSL, upper transistors UT1 and UT2 adjacent to the bit line BL, and a plurality of memory cell transistors MCT disposed between the lower transistors LT1 and LT2 and the upper transistors UT1 and UT2. In some example embodiments, the number of lower transistors LT1 and LT2 and the number of upper transistors UT1 and UT2 may be modified in various manners.

In various example embodiments, the upper transistors UT1 and UT2 may include a string select transistor, and the lower transistors LT1 and LT2 may include a ground select transistor. The gate lower lines LL1 and LL2 may be gate electrodes of the lower transistors LT1 and LT2, respectively. The word lines WL may be gate electrodes of the memory cell transistors MCT, and the gate upper lines UL1 and UL2 may be gate electrodes of the upper transistors UT1 and UT2, respectively.

In various example embodiments, the lower transistors LT1 and LT2 may include a lower erase control transistor LT1 and a ground select transistor LT2 connected in series. The upper transistors UT1 and UT2 may include a string select transistor UT1 and an upper erase control transistor UT2 connected in series. At least one of the lower erase control transistor LT1 and the upper erase control transistor UT2 may be used for an erase operation of erasing data stored in the memory cell transistors MCT using a GIDL phenomenon.

The common source line CSL, the first and second gate lower lines LL1 and LL2, the word lines WL, and the first and second gate upper lines UL1 and UL2 may be electrically connected to the decoder circuit 1110 through first connection interconnections 1115 extending from an interior of the first structure 1100F to the second structure 1100S. The bit lines BL may be electrically connected to the page buffer 1120 through second connection interconnections 1125 extending from the interior of the first structure 1100F to the second structure 1100S.

In the first structure 1100F, the decoder circuit 1110 and the page buffer 1120 may perform a control operation on at least one selected memory cell transistor, among the plurality of memory cell transistors MCT. The decoder circuit 1110 and the page buffer 1120 may be controlled by the logic circuit 1130. The semiconductor device 1100 may communicate with the controller 1200 through an input/output pad 1101 electrically connected to the logic circuit 1130. The input/output pad 1101 may be electrically connected to the logic circuit 1130 through an input/output connection interconnection 1135 extending from the interior of the first structure 1100F to the second structure 1100S.

The controller 1200 may include a processor 1210, a NAND controller 1220, and a host interface 1230. In some example embodiments, the data storage system 1000 may include a plurality of semiconductor devices 1100. In this case, the controller 1200 may control the plurality of semiconductor devices 1100.

The processor 1210 may control an overall operation of the data storage system 1000 including the controller 1200. The processor 1210 may operate according to predetermined or dynamically determined firmware, and may access the semiconductor device 1100 by controlling the NAND controller 1220. The NAND controller 1220 may include a controller interface 1221, processing communication with the semiconductor device 1100. A control instruction for controlling the semiconductor device 1100, data to be written to the memory cell transistors MCT of the semiconductor device 1100, and data to be read from the memory cell transistors MCT of the semiconductor device 1100 may be transmitted through the controller interface 1221. The host interface 1230 may provide a communication function between the data storage system 1000 and an external host. When a control instruction is received from the external host through the host interface 1230, the processor 1210 may control the semiconductor device 1100 in response to the control instruction.

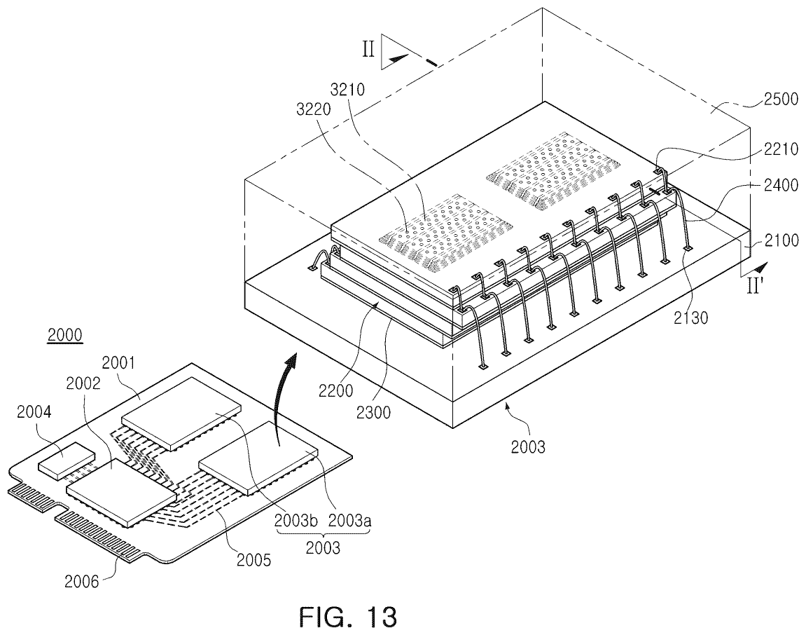

FIG. 13 is a schematic perspective view of a data storage system including a semiconductor device according to some example embodiments.

Referring to FIG. 13, a data storage system 2000 according to various example embodiments of the inventive concepts, may include a main substrate 2001, a controller 2002 mounted on the main substrate 2001, one or more semiconductor packages 2003, and a DRAM 2004. The semiconductor packages 2003 and the DRAM 2004 may be connected to the controller 2002 by interconnection patterns 2005 formed on the main substrate 2001.

The main substrate 2001 may include a connector 2006 including a plurality of pins coupled to an external host. The number and arrangement of the plurality of pins in the connector 2006 may vary depending on a communication interface between the data storage system 2000 and the external host. In some example embodiments, the data storage system 2000 may communicate with the external host according to one of interfaces such as universal flash storage (UFS), peripheral component interconnect express (PCI-Express), serial advanced technology attachment (SATA), M-Phy for universal serial bus (USB), and the like, however example embodiments are not limited thereto. In example embodiments, the data storage system 2000 may be operated by power supplied from the external host through the connector 2006. The data storage system 2000 may further include a power management integrated circuit (PMIC) distributing to the controller 2002 and a semiconductor package 2003, power supplied from the external host.

The controller 2002 may write data to the semiconductor package 2003 or read data from the semiconductor package 2003, and may improve operating speed of the data storage system 2000.

The DRAM 2004 may be a buffer memory for alleviating a speed difference between the semiconductor package 2003, a data storage space, and the external host. The DRAM 2004, included in the data storage system 2000, may also operate as a type of cache memory, and may provide a space for temporarily storing data in a control operation for the semiconductor package 2003. When the DRAM 2004 is included in the data storage system 2000, the controller 2002 may further include a DRAM controller for controlling the DRAM 2004 in addition to a NAND controller for controlling the semiconductor package 2003.

The semiconductor package 2003 may include a plurality of semiconductor packages 2003a and 2003b spaced apart from each other, the example embodiments show an arrangement with two semiconductor packages, but is not limited thereto. Each of the first and second semiconductor packages 2003a and 2003b may be a semiconductor package including a plurality of semiconductor chips 2200. Each of the first and second semiconductor packages 2003a and 2003b may include a package substrate 2100, semiconductor chips 2200 on the package substrate 2100, adhesive layers 2300 respectively disposed on lower surfaces of the semiconductor chips 2200, a connection structure 2400 electrically connecting the semiconductor chips 2200 and the package substrate 2100 to each other, and a molding layer 2500 covering the semiconductor chips 2200 and the connection structure 2400 on the package substrate 2100.

The package substrate 2100 may be a printed circuit board including package upper pads 2130. Each semiconductor chip 2200 may include an input/output pad 2210. The input/output pad 2210 may correspond to the input/output pad 1101 of FIG. 12, and the input/output connection interconnection 3265 may correspond to the input/output connection interconnection 1135 of FIG. 12. Each of the semiconductor chips 2200 may include gate stack structures 3210 and channel structures 3220. Each of the semiconductor chips 2200 may include the semiconductor device described above with reference to FIGS. 1 to 9.

In some example embodiments, the connection structure 2400 may be a bonding wire electrically connecting the input/output pad 2210 and the package upper pads 2130 to each other. Accordingly, in each of the first and second semiconductor packages 2003a and 2003b, the semiconductor chips 2200 may be electrically connected to each other using a bonding wire method, and may be electrically connected to the package upper pads 2130 of the package substrate 2100. In some example embodiments, in each of the first and second semiconductor packages 2003a and 2003b, the semiconductor chips 2200 may be electrically connected to each other by a connection structure including a through-silicon via (TSV) instead of the connection structure 2400 using the bonding wire method.

In various example embodiments, the controller 2002 and the semiconductor chips 2200 may be included in a single package. In some example embodiments, the controller 2002 and the semiconductor chips 2200 may be mounted on an interposer substrate, different from the main substrate 2001, and the controller 2002 and the semiconductor chips may be connected to each other by an interconnection formed on the interposer substrate 2200.

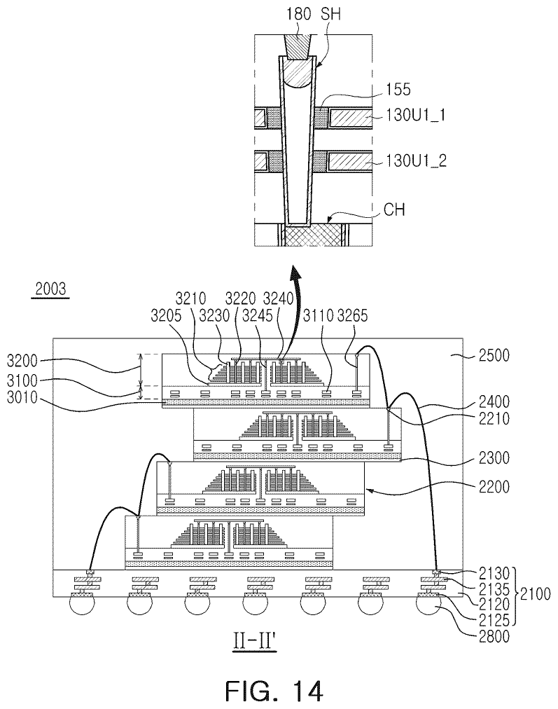

FIG. 14 is a schematic cross-sectional view of a semiconductor package according to some example embodiments. FIG. 14 illustrates the semiconductor package 2003 of FIG. 13, and schematically illustrates a region obtained by cutting the semiconductor package 2003 of FIG. 13 along line II-II′ according to some example embodiments.

Referring to FIG. 14, in the semiconductor package 2003, a package substrate 2100 may be a printed circuit board. The package substrate 2100 may include a package substrate body portion 2120, package upper pads 2130 (see FIG. 13) disposed on an upper surface of the package substrate body portion 2120, lower pads 2125 disposed on a lower surface of the package substrate body portion 2120 and exposed through the lower surface, and internal interconnections 2135 electrically connecting the upper pads 2130 and the lower pads 2125 to each other in the package substrate body portion 2120. The lower pads 2125 may be connected to interconnection patterns 2005 of a main substrate 2001 of a data storage system 2000 through conductive connection portions 2800, as illustrated in FIG. 13.

Each of semiconductor chips 2200 may include a semiconductor substrate 3010, and a first structure 3100 and a second structure 3200 sequentially stacked on the semiconductor substrate 3010. The first structure 3100 may include a peripheral circuit region including peripheral interconnections 3110. The second structure 3200 may include a common source line 3205, a gate stack structure 3210 on the common source line 3205, channel structures 3220 and gate isolation structures 3230 passing through the gate stack structure 3210, bit lines 3240 electrically connected to the channel structures 3220. As described above with reference to FIGS. 1 to 9, in each of the semiconductor chips 2200, a stud structure SH may pass through first upper gate electrodes 130U1_1 and 130U1_2, and upper gate dielectric layers 155 may be disposed on an outside of a stud hole in the stud structure SH.

Each of the semiconductor chips 2200 may include a through-interconnection 3245 electrically connected to the peripheral interconnections 3110 of the first structure 3100 and extending into the second structure 3200. The through-interconnection 3245 may be disposed on the outside of the gate stack structure 3210, and may further be disposed to pass through the gate stack structure 3210. Each of the semiconductor chips 2200 may further include the input/output pad 2210 (see FIG. 13) electrically connected to the peripheral interconnections 3110 of the first structure 3100.

The arrangement of a stud structure, passing through an upper select gate electrode, and an upper gate dielectric layer on an outside of the stud structure may be optimized, thereby providing a semiconductor device having improved mass productivity and a data storage system including the same.

While some example embodiments have been illustrated and described above, it may be apparent to those skilled in the art that modifications and variations could be made without departing from the scope of the inventive concepts as defined by the appended claims. Furthermore, example embodiments are not necessarily mutually exclusive with one another. For example, some example embodiments may include one or more features described with reference to one or more figures, and may also include one or more other features described with reference to one or more other figures.

What is claimed is:

1. A semiconductor device comprising:
a first semiconductor structure including a substrate, circuit elements on the substrate, and circuit interconnection lines on the circuit elements; and
a second semiconductor structure on the first semiconductor structure,
wherein the second semiconductor structure includes,
a plate layer,
a plurality of gate electrodes spaced apart from each other and stacked on the plate layer in a first direction, perpendicular to an upper surface of the plate layer, the gate electrodes including a lower select gate electrode, memory gate electrodes, and an upper select gate electrode sequentially stacked,
channel structures passing through the lower select gate electrode and the memory gate electrodes and extending in the first direction,
stud structures passing through the upper select gate electrode and respectively connected to the channel structures,
an upper gate dielectric layer surrounding the stud structures and recessed into the upper select gate electrode in a horizontal direction parallel to the upper surface of the plate layer,
the upper gate dielectric layer on an outside of each of the stud structures, and
upper isolation regions between the stud structures, passing through the upper select gate electrode and extending in a second direction, perpendicular to the first direction, wherein
each of the stud structures includes an upper channel layer covering an internal sidewall and a bottom surface of a stud hole passing through the upper select gate electrode, an upper filling insulating layer at least partially filling the stud hole on the upper channel layer.

2. The semiconductor device of claim 1, wherein the channel structures have a circular shape in the plan view with a first diameter, and the stud structures have a circular shape in the plan view with a second diameter less than the first diameter.

3. The semiconductor device of claim 1, wherein the stud structures partially recess upper portions of the channel structures.

4. The semiconductor device of claim 1, wherein the stud structures and the channel structures are shifted from each other in the horizontal direction.

5. The semiconductor device of claim 4, wherein the horizontal direction is a direction inclined with respect to the second direction.

6. The semiconductor device of claim 1, wherein the second semiconductor structure further includes:
cell contact plugs on the stud structures; and
bit lines on the cell contact plugs.

7. The semiconductor device of claim 6, wherein each of the cell contact plugs is aligned such that a respective central axis of each of the cell contact plugs corresponds to a respective central axis of the stud structures.

8. The semiconductor device of claim 1, wherein the upper select gate electrode and the memory gate electrodes include a same material.

9. The semiconductor device of claim 1, wherein a thickness of the upper select gate electrode is less than or equal to a thickness of each of the memory gate electrodes.

10. The semiconductor device of claim 1, wherein a thickness of the upper gate dielectric layer on an external side surface of the upper channel layer is in a range from 20% to 100% of a diameter of each of the stud structures.

11. The semiconductor device of claim 1, wherein the upper gate dielectric layer includes a plurality of dielectric layers stacked on an external side surface of the upper channel layer.

12. The semiconductor device of claim 1, wherein
the second semiconductor structure further includes lower isolation regions passing through the lower select gate electrode and the memory gate electrodes,
the lower isolation regions extend in the second direction, and
a portion of the upper isolation regions is on the lower isolation regions.

13. The semiconductor device of claim 1, wherein
the second semiconductor structure further includes lower isolation regions passing through the lower select gate electrode and the memory gate electrodes,
the lower isolation regions extend in the second direction, and
the lower isolation regions further pass through the upper select gate electrode and extend upwardly in some regions.

14. The semiconductor device of claim 1, wherein
the gate electrodes further include an erase gate electrode adjacent to the upper select gate electrode, and
the stud structures further pass through the erase gate electrode.

15. A semiconductor device comprising:
a plate layer;
a plurality of gate electrodes spaced apart from each other and stacked on the plate layer in a first direction, perpendicular to an upper surface of the plate layer, the gate electrodes including first gate electrodes in a lower portion thereof and at least one second gate electrode on the first gate electrodes;
channel structures passing through the first gate electrodes and extending in the first direction;
stud structures passing through the second gate electrode and respectively connected to the channel structures;
an upper gate dielectric layer on a side surface of each of the stud structures, the upper gate dielectric layer in contact with the second gate electrode; and
upper isolation regions between the stud structures, passing through the second gate electrode and extending in a second direction, perpendicular to the first direction.

16. The semiconductor device of claim 15, wherein the upper gate dielectric layer is on a same level as the second gate electrode.

17. The semiconductor device of claim 16, wherein the upper gate dielectric layer entirely surrounds the side surface of each of the stud structures on the level.

18. The semiconductor device of claim 15, further comprising:
cell contact plugs on the stud structures; and
bit lines on the cell contact plugs,
wherein the stud structures are electrically connected to the bit lines through the cell contact plugs.

19. A data storage system comprising:
a semiconductor storage device including a first semiconductor structure including circuit elements, a second semiconductor structure on a surface of the first semiconductor structure, and input/output pads electrically connected to the circuit elements; and
a controller electrically connected to the semiconductor storage device through the input/output pad, the controller configured to control the semiconductor storage device,
wherein the second semiconductor structure includes,
a plate layer,
a plurality of gate electrodes spaced apart from each other and stacked on the plate layer in a first direction, perpendicular to an upper surface of the plate layer, the gate electrodes including first gate electrodes in a lower portion thereof and at least one second gate electrode on the first gate electrodes,
channel structures passing through the first gate electrodes and extending in the first direction,
stud structures passing through the second gate electrode and respectively connected to the channel structures,
an upper gate dielectric layer protruding toward the second gate electrode on a side surface of each of the stud structures, and
upper isolation regions passing between the stud structures, through the second gate electrode and extending in a second direction, perpendicular to the first direction.

20. The data storage system of claim 19, wherein
the stud structures further include an upper channel layer in contact with the gate dielectric layer, and
the second gate electrode, the upper gate dielectric layer, and the upper channel layer form a string select transistor.
